(19) United States
(12) Patent Application Publication
(10) Pub. No.: US 2016/0105958 A1
(43) Pub. Date: Apr. 14, 2016

(54) MULTI-LAYER SUBSTRATE, ELECTRONIC DEVICE USING MULTI-LAYER SUBSTRATE, MANUFACTURING METHOD FOR MULTILAYER SUBSTRATE, SUBSTRATE, AND ELECTRONIC DEVICE USING SUBSTRATE

(71) Applicant: DENSO CORPORATION, Aichi (JP)

(72) Inventors: Toshihiro NAKAMURA, Kariya-city (JP); Shinya UCHIBORI, Kariya-city (JP); Koji NUMAZAKI, Kariya-city (JP); Atsushi KASHIWAZAKI, Kariya-city (JP); Masaji IMADA, Kariya-city (JP); Eiji YABUTA, Kariya-city (JP)

(21) Appl. No.: 14/785,422

(22) PCT Filed: Apr. 21, 2014
(86) PCT No.: PCT/JP2014/002233

§ 371 Date: Oct. 19, 2015

(30) Foreign Application Priority Data
Apr. 26, 2013 (JP) 2013-094373
Jun. 13, 2013 (JP) 2013-124970

(51) Int. Cl. H05K 1/03; H05K 3/00; H05K 3/06; H05K 3/34; H01L 23/498; H05K 1/18

(52) U.S. Cl. CPC H05K 1/0306; H01L 23/49822; H01L 23/49827; H05K 1/038; H05K 1/0313; H05K 1/181; H05K 3/067; H05K 3/341; H05K 3/0067; H05K 2201/10022; H05K 2201/10015; H05K 2201/10166

(57) ABSTRACT

In a multi-layer substrate, a glass cloth of a build-up layer is deformed toward a land below the land. A thickness of a resin layer of the build-up layer from the glass cloth to a surface adjacent to the land is set to be smaller than a dimension from the glass cloth to a front surface of a core layer. With the above configuration, a progress or an enlargement of a crack can be suppressed from a stage in which the crack is smaller. Therefore, the progress and the enlargement of the crack can be delayed. As a result, even if the crack is generated, an insulating property between the land and an inner layer wire is ensured, and the land and the inner layer wire can be restricted from being short-circuited.

### CROSS REFERENCE TO RELATED APPLICATIONS

This application is based on Japanese Patent Application No. 2013-94373 filed on Apr. 26, 2013 and Japanese Patent Application No. 2013-124970 filed on Jun. 13, 2013, the disclosures of which are incorporated herein by reference.

### TECHNICAL FIELD

The present disclosure relates to a multi-layer substrate having a land on which electronic components are mounted through soldering, an electronic device using the multi-layer substrate, a method of manufacturing the multi-layer substrate, a substrate, and an electronic device using the substrate.

### BACKGROUND ART

Up to now, as the electronic device of this type, the following device has been proposed (for example, refer to PTL 1).

Specifically, the electronic device includes a multi-layer substrate in which a core layer and a build-up layer made of resin are laminated, an inner layer wire is formed between the core layer and the build-up layer, and a land is formed on one surface of the build-up layer opposite to the core layer. The land includes a metal film formed into a plate-shape, and a metal plating that is higher in solder wettability than the metal film, and formed on one surface of the metal film opposite to the build-up layer, and an overall side surface of the metal film. Electronic components such as a power element and a control element are mounted over the land through the solder. One surface side of the multi-layer substrate including the electronic components is covered with a mold resin for improving an environmental (corrosion) resistance to configure the electronic device.

A substrate disclosed in PTL 2 has been proposed. The substrate includes an insulating layer in which both surfaces of a glass cloth are sealed with a resin material, a first conductor disposed on a front surface side of the insulating layer, and a second conductor disposed on a rear surface side of the insulating layer.

The insulating layer includes the glass cloth, a first resin layer made of a resin material and sealing a first conductor side of the glass cloth, and a second resin layer made of a resin material and sealing a second conductor side of the glass cloth.

### PRIOR ART LITERATURES

### Patent Literatures

PTL 1: JP S61-135191 A
PTL 2: JP 2007-176169 A

### SUMMARY OF INVENTION

### Technical Problem

For example, as illustrated in FIG. 17, in the electronic device in which an electronic component J2 is covered with a mold resin J1, a metal plating J4 is formed on one surface J1a and a side surface J3b of a metal film J3, and a solder J6 spreads to a side surface of a land J5. An adhesion force of the mold resin J1 and the solder J6 is normally lower than an adhesive force of the mold J1 and the land J5 (metal). For that reason, in the above electronic device, the mold resin J1 is easily peeled off from an interface with the solder J6, and when the mold resin J1 is peeled off from the solder J6, a crack J8 is generated in a build-up layer J7.

In other words, a stress caused by peeling off the mold resin J1 from the solder J6 is propagated to the build-up layer J7, and the crack J8 is generated in the build-up layer J7.

Because a displacement of the land J5 cannot be suppressed by the mold resin J1 if the mold resin J1 is peeled off, the land J5 can be expanded and contracted according to a use environment. Because the land J5 and the build-up layer J7 are different in thermal expansion coefficient from each other, the stress is applied to the build-up layer J7. In particular, in a low-temperature use environment, with the contraction of the land J5, a significant tensile stress is applied to an end of the interface of the build-up layer J7 with the land J5, and the crack J8 is generated in the build-up layer J7.

When the crack J8 generated in the build-up layer J7 reaches the inner layer wire, if foreign matter such as water enters the crack J8, the land J5 and the inner layer wire are likely to be short-circuited.

The present inventors have focused on a linear expansion coefficient of the first resin layer and a liner expansion coefficient of the first conductor in the substrate of the above PTL 2, and studied that the generation of the crack is suppressed.

The linear expansion coefficient of the glass cloth is smaller than the linear expansion coefficient of the first resin layer. For that reason, when the glass cloth large in thickness is used for the purpose of enhancing a strength of the insulating layer, a rate of the glass cloth to the insulating layer increases. As a result, the linear expansion coefficient of the insulating layer on the first conductor side is affected by the linear expansion coefficient of the glass cloth, and lowered. The linear expansion coefficient of the insulating layer on the first conductor side represents a rate of a change in a length of a portion of the insulating layer on the first conductor side to a temperature rise. For that reason, when the rate of the glass cloth to the insulating layer increases, a difference between the linear expansion coefficient of the insulating layer on the first conductor side and the linear expansion coefficient of the first conductor becomes larger. Therefore, a larger internal stress may be generated in the interface between the insulating layer and the first conductor with a change in temperature. For that reason, when the change in temperature is repetitively generated, a crack (hereinafter, the crack thus generated in the interface between the insulating layer and the first conductor is called “first conductor side starting point crack”) caused by the internal stress may be generated, in the first resin layer of the insulating layer.

On the other hand, the glass cloth is woven with multiple horizontal yarns made of multiple glass fibers extending in a horizontal direction, and multiple vertical yarns made of multiple glass fibers extending in a vertical direction. In the glass cloth, the respective adjacent two horizontal yarns of the multiple horizontal yarns and the respective adjacent two vertical yarns of the multiple vertical yarns are configured to surround a basket hall.

For example, when the first conductor side starting point crack is generated, the crack may progress to a second resin layer through the basket hall (between the adjacent two glass fibers of the multiple glass fibers) of the glass cloth.

On the contrary, as described above, the glass cloth is woven with the multiple horizontal yarns and the multiple vertical yarns. For that reason, the multiple glass fibers configuring the multiple horizontal yarns or the multiple vertical yarns have a bridge effect of reducing a progress rate of the first conductor side starting point crack in the second resin layer. The progress rate represents a rate at which the crack progresses to the second conductor side from the glass cross side in the second resin layer.

In order to reduce a difference between the linear expansion coefficient of the insulating layer on the first conductor side and the linear expansion coefficient of the first conductor described above, it is proposed that the thickness of the first resin layer increases to reduce an influence of the linear expansion coefficient of the glass cloth as compared with the linear expansion coefficient of the insulating layer on the first conductor side. However, on the other hand, when the thickness of the insulating layer is kept constant, and the thickness of the first resin layer unnecessarily increases, the thickness of the second resin layer decreases. For that reason, the thickness of the second resin layer having the above bridge effect decreases. In other words, the thickness of a region in which the progress rate of the first conductor side starting point crack is reduced due to the bridge effect in the insulating layer decreases. Therefore, a time required since the first conductor side starting point crack progresses to the second resin layer until the crack reaches a surface of the second resin layer on the second conductor side becomes shorter. In other words, there is a concern about a reduction in the strength to the first conductor side starting point crack as the entire substrate.

It is a first object of the present disclosure to provide a multi-layer substrate that can restrict a land and an inner layer wire from being short-circuited even if a crack is generated in a build-up layer, an electronic device using the multi-layer substrate, and a method of manufacturing the multi-layer substrate. Further, it is a second object of the present disclosure to provide a substrate that performs both of the suppression of the generation of a first conductor side starting point crack and an improvement in the strength of the overall substrate to the first conductor side starting point crack, and an electronic device using the substrate.

### Solution to Problem

According to a first aspect of the present disclosure, a multi-layer substrate includes: a core layer having a front surface; an inner layer wire formed on the front surface of the core layer; a build-up layer that is arranged on the front surface of the core layer in a state where the build-up layer covers the inner layer wire, and includes a glass cloth woven with glass fibers into a film shape, and a resin layer that covers both of front and rear surfaces of the glass cloth; and a land that is formed on a surface of the build-up layer opposite to the core layer, over which an electronic component is mounted through a solder. In a portion of the build-up layer, which is located between the land and the core layer, the glass cloth is extruded toward the land, and a thickness of the resin layer from the glass cloth to the surface adjacent to the land is smaller than a dimension from the glass cloth to the front surface of the core layer in the portion.

According to the above configuration, the glass cloth of the build-up layer between the land and the core layer is deformed toward the land. The thickness of the resin layer from the glass cloth to the surface adjacent to the land is smaller than the dimension from the glass cloth to the front surface of the core layer. With the above configuration, a progress or an enlargement of a crack can be suppressed from a stage in which the crack is smaller. Therefore, the progress and the enlargement of the crack can be delayed. As a result, even if the crack is generated, an insulating property between the land and an inner layer wire is ensured, and the land and the inner layer wire can be restricted from being short-circuited.

For example, a method of manufacturing the multi-layer substrate includes: preparing a core layer having an inner layer wire on a front surface of the core layer; preparing a build-up layer having a glass cloth and a resin layer having the same thickness on both surfaces of the glass cloth; laminating the build-up layer on the front surface of the core layer; laminating a metal plate on a surface of the build-up layer opposite to the core layer; deforming a portion of the glass cloth corresponding to the inner layer wire in a direction away from the core layer so that the portion of the glass cloth is extruded toward the metal plate by the inner layer wire than a portion of the glass cloth without corresponding to the inner layer wire while allowing a resin forming the resin layer of the build-up layer to flow around the inner layer wire by heating a laminated body having the core layer, the build-up layer, and the metal plate while pressurizing the laminated body in a laminating direction; and forming a surface layer wire in a portion of the metal plate corresponding to the inner layer wire by patterning the metal plate.

According to a second aspect of the present disclosure, a substrate includes: an insulating layer; a first conductor arranged on one side of the insulating layer in a thickness direction of the insulating layer; and a second conductor arranged on the other side of the insulating layer in the thickness direction. The insulating layer includes a glass cloth, and a resin layer that seals a surface of the glass cloth adjacent to the first conductor and a surface of the glass cloth adjacent to the second conductor with an electrically insulating resin material. A linear expansion coefficient of the glass cloth is lower than a linear expansion coefficient of the first conductor, and lower than a linear expansion coefficient of a portion of the resin layer adjacent to the first conductor. A dimension between the first conductor and the glass cloth in the thickness direction of the insulating layer is defined as A. A dimension of the glass cloth in the thickness direction is defined as B. A dimension between a surface of the insulating layer adjacent to the second conductor and the glass cloth in the thickness direction is defined as C. The dimensions A, B, and C satisfy a size relationship of C>A>B. The thickness direction of the insulating layer represents a direction orthogonal to a direction along a surface of the insulating layer.

According to the above configuration, the size relationship of A>B is first satisfied. For that reason, as compared with a case in which a size relationship of A<B is satisfied, a distance between the first conductor and the glass cloth can be increased. Therefore, an influence of the linear expansion coefficient of the glass cloth can be reduced as compared with the linear expansion coefficient of the portion of the insulating layer adjacent to the first conductor. As a result, a difference between the linear expansion coefficient of the portion of the insulating layer adjacent to the first conductor and the linear expansion coefficient of the first conductor can be reduced. For that reason, an internal stress can be restricted from being generated on an interface between the insulating layer and the first conductor due to a temperature change. As a result, the first conductor side starting point crack can be primarily restricted from being generated on the portion of the resin layer (hereinafter called “first resin layer”) adjacent to the first conductor due to the temperature change.

If the first conductor side starting point crack is generated in the first resin layer of the resin layer in the thickness direction, there is a risk that the first conductor side starting point crack progresses to the portion of the resin layer (hereinafter referred to as “second resin layer”) adjacent to the second conductor.

According to a third aspect of the present disclosure, in the substrate of the second aspect, the glass cloth is woven with a plurality of first yarns each made of a glass fiber extending in a first direction, and a plurality of second yarns each made of a glass fiber extending in a second direction orthogonal to the first direction. For that reason, the glass fibers configuring the plurality of first yarns or the plurality of second yarns have a bridge effect of reducing a progress rate at which the first conductor side starting point crack progresses in the second resin layer. That is, the glass cloth has the bridge effect of reducing the progress rate at which the first conductor side starting point crack progresses in the second resin layer. The progress rate of the first conductor side starting point crack represents a rate at which the first conductor side starting point crack progresses to the surface of the second conductor side from the glass cross side in the second resin layer.

In the substrate according to the second and third aspects, the size relationship of A>B as well as C>A is satisfied. For that reason, as compared with a case in which the size relationship of A>C is satisfied when the thickness of the substrate is kept constant, a thickness of a region in which the progress rate of the first conductor side starting point crack is reduced due to the bridge effect becomes large. As a result, a time required since the first conductor side starting point crack is generated in the second resin layer until the crack progresses to the surface of the second resin layer on the second conductor side can be lengthened. Therefore, the strength of the overall substrate against the first conductor side starting point crack can be improved.

As described above, the substrate that performs both of the suppression of the generation of the first conductor side starting point crack and the improvement in the strength of the overall substrate against the first conductor side starting point crack can be provided.

### BRIEF DESCRIPTION OF DRAWINGS

The above and other objects, features and advantages of the present disclosure will become more apparent from the following detailed description made with reference to the accompanying drawings, in which:

FIG. 1 is a cross-sectional view of an electronic device according to a first embodiment of the present disclosure;

FIG. 2 is an enlarged view of a region II in FIG. 1;

FIG. 3A is a partially enlarged cross-sectional view of an electronic device when a build-up layer is of a conventional structure as one comparative example;

FIG. 3B is a partially enlarged view of an electronic device when a glass cloth in the build-up layer is disposed totally closer to a land as another comparative example;

FIGS. 4A to 4D are cross-sectional views illustrating a process of manufacturing a multi-layer substrate illustrated in FIG. 1;

FIGS. 5A to 5D are cross-sectional views illustrating a process of manufacturing the multi-layer substrate subsequent to FIGS. 4A to 4D;

FIGS. 6A to 6D are cross-sectional views illustrating a process of manufacturing the multi-layer substrate subsequent to FIGS. 5A to 5D;

FIG. 7 is a cross-sectional schematic view illustrating a process of manufacturing a build-up layer according to the first embodiment;

FIGS. 8A and 8B are cross-sectional views illustrating a state of deformation of a glass cloth within the build-up layer according to the first embodiment;

FIG. 9 is a cross-sectional view of an electronic device according to a second embodiment of the present disclosure;

FIG. 10 is an enlarged view of a portion X of a core layer in FIG. 9;

FIG. 11A is an enlarged view of a portion XIA and a portion XIB in FIG. 9;

FIG. 11B is an enlarged view of a portion XIC and a portion XID in FIG. 9;

FIG. 12A is an enlarged view of a glass cloth in FIGS. 11A and 11B;

FIG. 12B is an enlarged cross-sectional view of the glass cloth illustrated in FIG. 12A;

FIGS. 13A to 13D are cross-sectional views illustrating a process of manufacturing a multi-layer substrate illustrated in FIG. 9;

FIGS. 14A to 14D are cross-sectional views illustrating a process of manufacturing the multi-layer substrate subsequent to FIGS. 13A to 13D;

FIGS. 15A to 15D are cross-sectional views illustrating a process of manufacturing the multi-layer substrate subsequent to FIGS. 14A to 14D;

FIG. 16 is a partially enlarged view of a multi-layer substrate in a comparative example of the second embodiment; and

FIG. 17 is an enlarged cross-sectional view of an electronic device illustrating a state in which a crack is generated in a multi-layer substrate as a related art.

### DESCRIPTION OF EMBODIMENTS

Hereinafter, embodiments according to the present disclosure will be described with reference to the drawings. In each of the following embodiments, the description will be provided using the same reference numerals for the same or equivalent portions.

### First Embodiment

A first embodiment of the present disclosure will be described. An electronic device according to the present embodiment is mounted on a vehicle such as an automobile, and applied for driving various electronic devices for the vehicle.

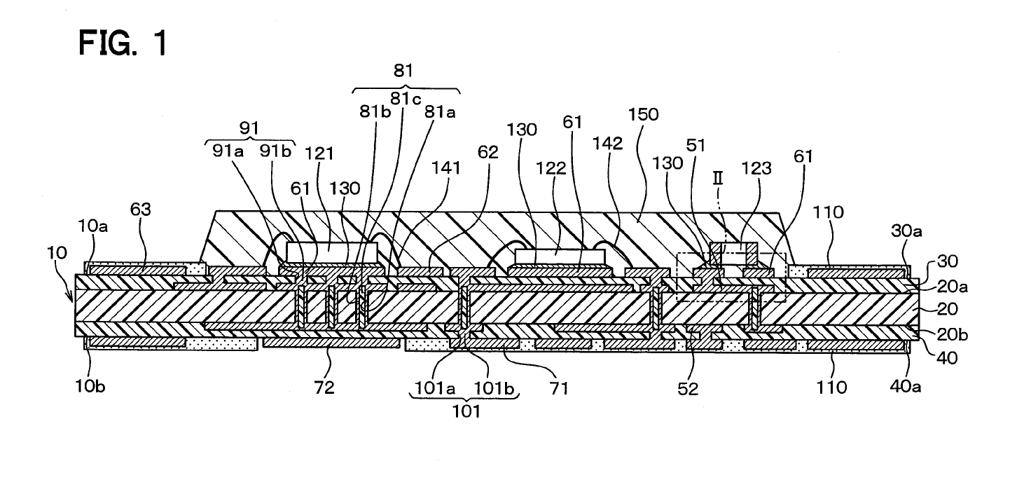

As illustrated in FIG. 1, the electronic device includes a multi-layer substrate 10 having one surface 10a and the other surface 10b, and electronic components 121 to 123 mounted on the one surface 10a of the multi-layer substrate 10. The one surface 10a of the multi-layer substrate 10 is sealed with a mold resin 150 together with the electronic components 121 to 123 to configure the electronic device.

The multi-layer substrate 10 is a laminated substrate including a core layer 20 as an insulating resin layer, a build-up layer 30 disposed on a front surface 20a of the core layer 20, a build-up layer 40 disposed on a rear surface 20b of the core layer 20, and inner layer wires 51, 52.

The core layer 20 and the build-up layers 30, 40 are each made of prepreg obtained by sealing both surfaces of a glass cloth woven with glass fibers into a film shape with a thermosetting resin, and the resin of the prepreg is epoxy resin or the like. A filler excellent in electric insulation and heat radiation such as alumina or silica may be contained in the resin of the prepreg as occasion demands.

The patterned front surface side inner layer wire 51 (hereinafter referred to merely as “inner layer wire 51”) is formed on an interface of the core layer 20 and the build-up layer 30. Likewise, the patterned rear surface side inner layer wire 52 (hereinafter referred to merely as “inner layer wire 52”) is formed on an interface of the core layer 20 and the build-up layer 40.

Patterned front surface side surface layer wires 61 to 63 (hereinafter referred to simply as “surface layer wires 61 to 63”) are formed on a surface 30a of the build-up layer 30. In the present embodiment, the surface layer wires 61 to 63 include mounting lands 61 on which the electronic components 121 to 123 are mounted, bonding lands 62 that are electrically connected to the respective electronic components 121 and 122 through bonding wires 141 and 142, and a surface pattern 63 that is electrically connected to an external circuit.

Likewise, patterned rear surface side surface layer wires 71 and 72 (hereinafter referred to simply as “surface layer wires 71 and 72”) are formed on a surface 40a of the build-up layer 40. In the present embodiment, the surface layer wires 71 and 72 include a rear surface pattern 71 connected to the inner layer wire 52 through a filled via to be described later, and a heat sink pattern 72 (hereinafter referred to merely as “HS pattern 72”) having a heat radiation heat sink.

The surface 30a of the build-up layer 30 means one surface of the build-up layer 30 opposite to the core layer 20, which is a surface forming the one surface 10a of the multi-layer substrate 10. The surface 40a of the build-up layer 40 means one surface of the build-up layer 40 opposite to the core layer 20, which is a surface forming the other surface 10b of the multi-layer substrate 10. The inner layer wires 51, 52, the surface layer wires 61 to 63, and the surface layer wires 71 and 72 are configured by appropriately laminating metal foils or metal plating made of copper on each other, which will be described in detail later.

The inner layer wire 51 and the inner layer wire 52 are electrically and thermally connected to each other through a through-via 81 that penetrates through the core layer 20. Specifically, the through-via 81 is configured in such a manner that a through-electrode 81b made of copper is formed on a wall surface of a through-hole 81a that penetrates through the core layer 20 in a thickness direction of the core layer 20, and an interior of the through-hole 81a is filled with a filler 81c.

The inner layer wire 51 as well as the surface layer wires 61 to 63, and the inner layer wire 52 as well as the surface layer wires 71 and 72 are electrically and thermally connected to each other through filled vias 91 and 101 that appropriately penetrate through the build-up layers 30 and 40 in the thickness direction of those layers, respectively. Specifically, the filled vias 91 and 101 are configured in such a manner that through-holes 91a and 101a that penetrate through the build-up layers 30 and 40 in the thickness direction are filled with through-electrodes 91b and 101b made of copper or the like.

The filler 81c is made of resin, ceramic, or metal, and made of epoxy resin in the present embodiment. The through-electrodes 81b, 91b, and 101b are made of metal plating made of copper or the like.

The surfaces 30a and 40a of the respective build-up layers 30 and 40 are formed with a solder resist 110 that covers the front surface pattern 63 and the rear surface pattern 71. An opening is defined in the solder resist 110 that covers the front surface pattern 63 in a cross-section different from that in FIG. 1. The opening exposes a portion of the front surface pattern 63 which is connected to the external circuit.

The electronic components 121 to 123 include a power element 121 large in heat generation such as an IGBT (insulated gate bipolar transistor) or a MOSFET (metal oxide semiconductor field effect transistor), a control element 122 such as a microcomputer, and a passive element 123 such as a chip capacitor or a resistor. The respective electronic components 121 to 123 are mounted on the lands 61 through solders 130, and electrically and mechanically connected to the lands 61. The power element 121 and the control element 122 are also electrically connected to the lands 62 formed around the power element 121 and the control element 122 through the bonding wires 141 and 142 made of aluminum, gold or the like.

In the above description, the electronic components 121 to 123 are exemplified by the power element 121, the control element 122, and the passive element 123, but the electronic components 121 to 123 are not limited to those components.

The mold resin 150 is configured to seal the lands 61, 62, and the electronic components 121 to 123, and formed with general mold material such as epoxy resin through a transfer mold technique or a compression mold technique using a mold.

In the present embodiment, the mold resin 150 is formed on only the one surface 10a of the multi-layer substrate 10. In other words, the electronic device according to the present embodiment is of a so-called half-mold structure. On the other surface 10b side of the multi-layer substrate 10, a heat sink is disposed on the HS pattern 72 through a heat radiation grease although not particularly shown.

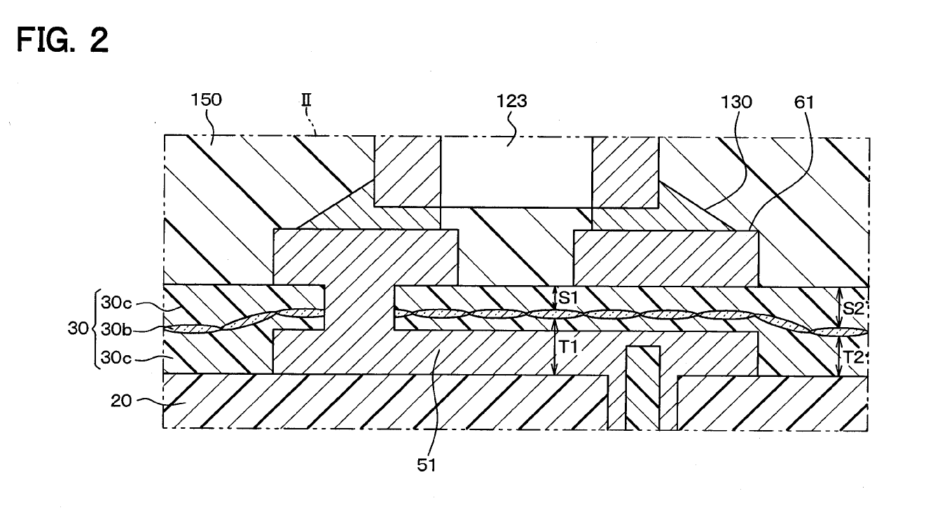

A basic configuration of the electronic device according to the present embodiment is described above. Subsequently, a description will be given of a structure of the build-up layer 30 below the lands 61 on which the electronic components 121 to 123 are mounted, which is features of the present embodiment. FIG. 2 illustrates a structure of the build-up layer 30 below the land 61 on which the passive element 123 is mounted, and the description will be made with reference to FIG. 2.

As illustrated in FIG. 2, the land 61 on which the passive element 123 is mounted is electrically and physically connected to an electrode of the passive element 123 through the solders 130. In the present embodiment, because it is assumed that a resistor or a capacitor is assumed as the passive element 123, respective electrodes are provided on both ends of the passive element 123, and the respective lands 61 formed at positions corresponding to the respective electrodes of the passive element 123 are connected to the respective electrodes of the passive element 123 on both ends of the passive element 123.

On the other hand, as described above, the build-up layer 30 is made of prepreg in which both surfaces of a glass cloth 30b are sealed with thermosetting resin layers 30c. A portion of the glass cloth 30b disposed in the build-up layer 30, which is located below each of the lands 61, that is, between the land 61 and the core layer 20, is deformed toward the land 61. With the above configuration, a thickness S1 of the resin layer 30c from the glass cloth 30b to a surface of the resin layer 30c adjacent to the land 61 (the surface opposite to the core layer 20) is set to be thinner than a thickness (dimension) T1 from the glass cloth 30b to the core layer 20. Specifically, the inner layer wire 51 is disposed at a position below each land 61, and the glass cloth 30b is extruded by the inner layer wire 51, and approaches toward the land 61. The thickness S1 of a portion corresponding to the land 61 from the glass cloth 30b to a surface of the resin layer 30c adjacent to the land 61 is set to be smaller than a thickness S2 of a portion not corresponding to the land 61 (a portion corresponding to an outside of the land 61) from the glass cloth 30b to the surface of the resin layer 30c adjacent to the land 61.

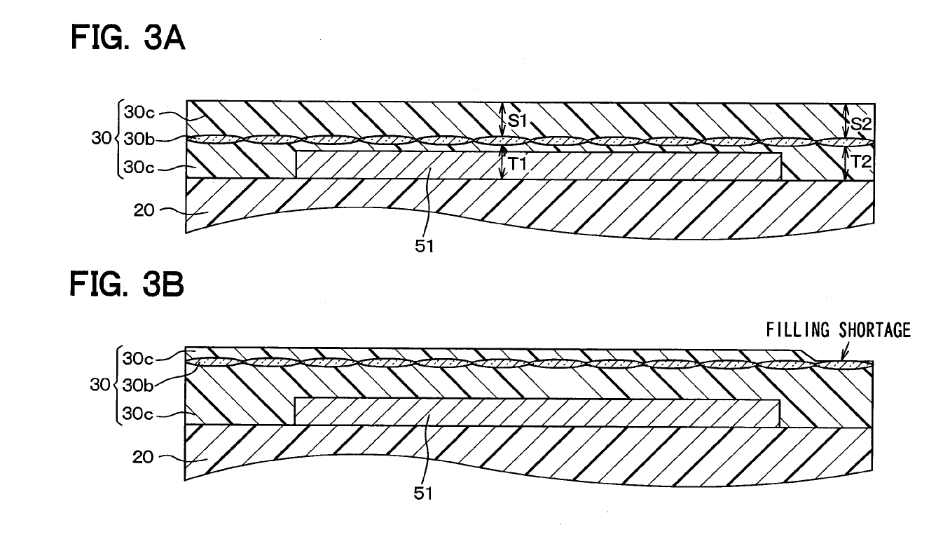

When the glass cloth 30b is disposed in the build-up layer 30, since the glass cloth 30b is provided for the purpose of ensuring a strength of the build-up layer 30, the glass cloth 30b has a sufficient thickness to ensure the strength. For that reason, even when the build-up layer 30 is brought in close contact with the core layer 20, the glass cloth 30b is kept flat and hardly deformed. As will be described later, the build-up layer 30 is manufactured by disposing the resin layers 30c having substantially the same thickness on both surfaces of the glass cloth 30b. When the build-up layer 30 is brought into close contact with the core layer 20, the inner layer wire 51 is embedded in the resin layer 30c. For that reason, due to the nature, as illustrated in FIG. 3A, in the resin layers 30c on both surfaces of the glass cloth 30b, the thickness S1 from the glass cloth 30b to the surface opposite to the core layer 20 at a position where the inner layer wire 51 is formed is substantially the same as the thickness T1 from the glass cloth 30b to the core layer 20. The thicknesses S2 and T2 of the resin layer 30c at a position where the inner layer wire 51 is not formed are also substantially the same as each other. Hence, the glass cloth 30b is biased to a lower side, that is, the inner layer wire 51.

On the contrary, in the present embodiment, with a reduction in the strength of the glass cloth 30b while the strength of the build-up layer 30 is kept to some degree, the glass cloth 30b is deformed at a lower position of the land 61, and the glass cloth 30b approaches the land 61 side. Specifically, the thickness of the glass cloth 30b is set to be equal to or larger than 10 μm and equal to or smaller than 30 μm, for example, as thin as 20 μm, to reduce the strength of the glass cloth 30b. With the above configuration, the glass cloth 30b can approach the land 61 to obtain the following advantages.

For example, when the mold resin 150 is peeled off from the solder 130 that connects the passive element 123 to the land 61, and a crack is generated in the build-up layer 30 through an interface of those components, the crack gradually progresses to the glass cloth 30b. In this situation, the progress of the crack cannot perfectly stop in the glass cloth 30b. However, since the strength of the glass cloth 30b is sufficiently higher than the strength of the resin layer 30c, and the glass cloth 30b is woven with the glass fibers, the crack can progress from only a gap of the glass cloth 30b. For that reason, a crack width is smaller below the glass cloth 30b. The application of a stress to the resin layer 30c is reduced due to the presence of the glass cloth 30b high in strength, and the progress or enlargement of the crack from the glass cloth 30b toward the core layer 20 can be suppressed.

The above advantage is obtained by the provision of the glass cloth 30b, but the progress or the enlargement of the crack can be suppressed from a stage where the crack is smaller as the glass cloth 30b is closer to the land 61. For that reason, the progress and the enlargement of the crack can be delayed. Therefore, even if the crack is generated, an insulating property between the land and an inner layer wire is ensured, and the land and the inner layer wire can be restricted from being short-circuited.

If the glass cloth 30b is set closer to the land 61, it is conceivable that the entirety of the glass cloth 30b may be set closer to the land 61. However, the manufacture in which the thicknesses of the resin layers 30c disposed on both surfaces of the glass cloth 30b are made different from each other causes a manufacturing process to be complicated, and is not preferable. In the manufacture, a process of bringing the build-up layer 30 into close contact with the core layer 20 must be performed while recognizing the front and rear surfaces. Further, when the thickness of the resin layer 30c adjacent to the land 61 is thinned, a filling shortage of the resin layer 30c occurs at a position outside of the land 61 as illustrated in FIG. 3B, resulting in such a problem that the glass cloth 30b is exposed. For that reason, it is preferable that, at a position away from the land 61, the thickness S2 of the resin layer 30c on the side adjacent to the land 61 than the glass cloth 30b is set to be substantially the same (S2≈T2) as the thickness T2 of the resin layer 30c on the side adjacent to the core layer 20 to perform the sure filling of the resin layer 30c.

Therefore, in the present embodiment, the resin layer 30c on the side adjacent to the land 61 and below the land 61 is basically thinned while using the build-up layer 30 having the resin layers 30c of the same thickness on both of the front and rear surfaces of the glass cloth 30b. This makes it possible to restrict the land and the inner layer wire 51 from being short-circuited even if the crack is generated in the build-up layer 30. The filling shortage of the resin layer 30c can be restricted from occurring outside of the land 61.

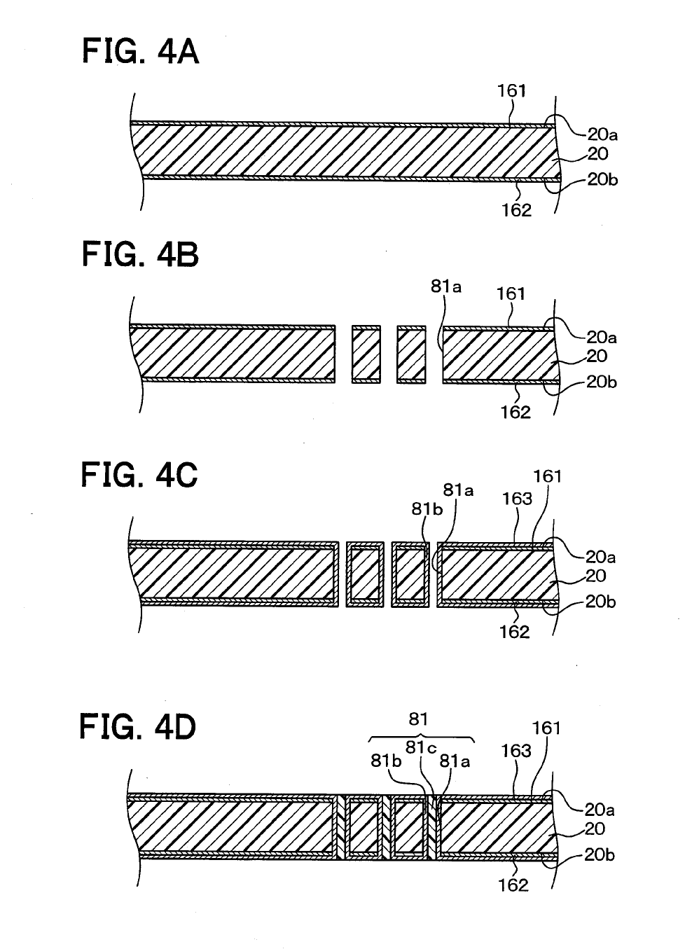

The configuration of the electronic device according to the present embodiment is described above. Subsequently, a method of manufacturing the above electronic device will be described with reference to FIGS. 4A to 4D, 5A to 5D, and 6A to 6D. FIGS. 4A to 4D, 5A to 5D, and 6A to 6D are cross-sectional views of the neighborhood of a portion of the multi-layer substrate 10 on which the power element 121 is mounted.

First, as illustrated in FIG. 4A, a structure in which metal foils 161 and 162 such as copper foils are disposed on the front surface 20a and the rear surface 20b of the core layer 20 is prepared. Further, as illustrated in FIG. 4B, the through-holes 81a that penetrate through the metal foil 161, the core layer 20, and the metal foil 162 are produced by a drill.

Thereafter, as illustrated in FIG. 4C, electroless plating or electroplating is performed to form a metal plating 163 made of copper on wall surfaces of the through-holes 81a, and the metal foils 161, 162. With the above process, through-electrodes 81b formed of the metal plating 163 are formed on the wall surfaces of the respective through-holes 81a. It is preferable that the electroless plating and the electroplating are performed with the use of catalyst such as palladium.

Subsequently, as illustrated in FIG. 4D, the filler 81c is disposed in spaces surrounded by the metal plating 163. With this process, the through-vias 81 each having the through-hole 81a, the through-electrode 81b, and the filler 81c are produced.

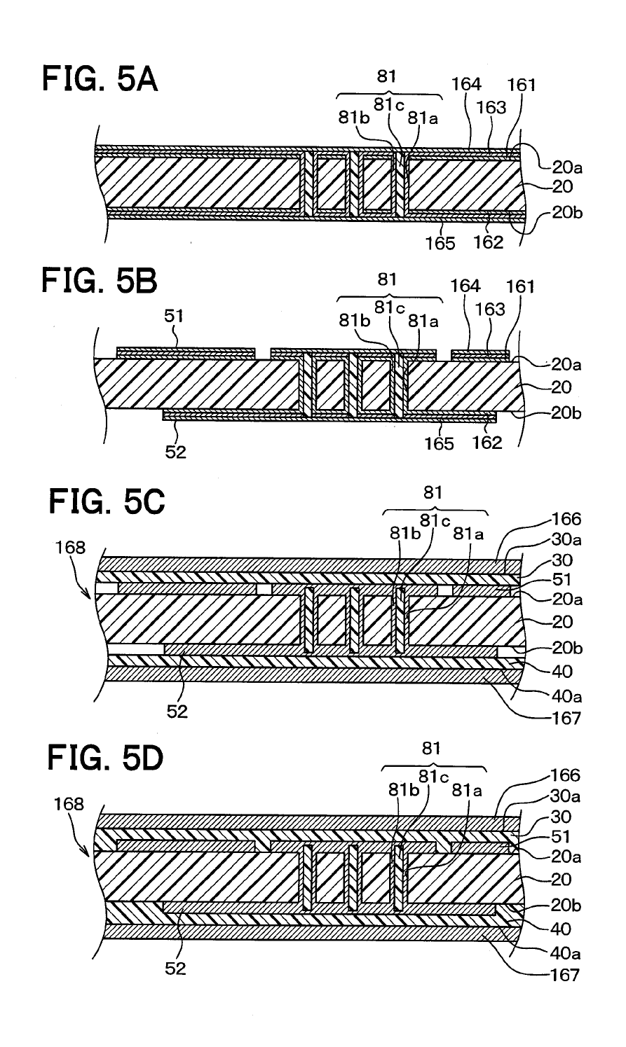

Thereafter, as illustrated in FIG. 5A, a so-called cover plating is performed by the electroless plating and the electroplating to form metal platings 164 and 165 made of copper on the metal plating 163 and the filler 81c.

Then, as illustrated in FIG. 5B, a resist not shown is disposed on the metal platings 164 and 165. Further, wet etching is performed with the resist as a mask, and the metal plating 164, the metal plating 163, and the metal foil 161 are appropriately patterned to form the inner layer wire 51. The metal plating 165, the metal plating 163, and the metal foil 162 are appropriately patterned to form the inner layer wire 52. In other words, in the present embodiment, the inner layer wire 51 is configured by laminating the metal foil 161, the metal plating 163, and the metal plating 164 on each other, and the inner layer wire 52 is configured by laminating the metal foil 162, the metal plating 163, and the metal plating 165 on each other.

In FIG. 5C and the subsequent drawings, the metal foil 161, the metal plating 163, and the metal plating 164 as well as the metal foil 162, the metal plating 163, and the metal plating 165 are collectively illustrated as one layer.

Thereafter, as illustrated in FIG. 5C, the build-up layer 30 and a metal plate 166 made of copper are prepared, and the build-up layer 30 and the metal plate 166 made of copper are laminated on the inner layer wire 51 on the front surface 20a side of the core layer 20. The build-up layer 40 and a metal plate 167 made of copper are laminated on the inner layer wire 52 on the rear surface 20b side of the core layer 20. In the above manner, a laminated body 168 in which the metal plate 166, the build-up layer 30, the inner layer wire 51, the core layer 20, the inner layer wire 52, the build-up layer 30, and the metal plate 167 are laminated on each other in order from the top is configured.

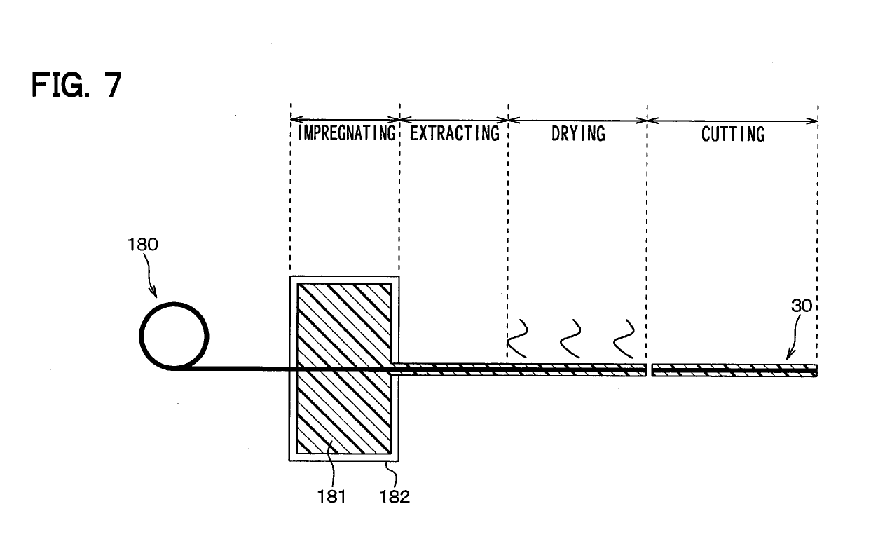

The build-up layers 30 and 40 are manufactured as follows for preparation. Specifically, in preparing the build-up layer 30, as illustrated in FIG. 7, a glass cloth sheet 180 wound into a roll is prepared, and an impregnation step of impregnating the glass cloth sheet 180 with a liquid resin 181 mixed with a filter and an additive accommodated in a resin solution tank 182 is performed. Then, an extraction step of extracting the glass cloth sheet 180 from the resin solution tank 182 is performed. The step leads to a state in which the liquid resin 181 adheres to both of the front and rear surfaces of the glass cloth sheet 180. Thereafter, a drying step of drying and provisionally curing the liquid resin 181 is performed. Further, a cutting step of cutting the dried liquid resin 181 into an appropriate size is performed, as a result of which the build-up layer 30 having the glass cloth 30b configured by the cut glass cloth sheet 180, and the resin layer 30c configured by the dried liquid resin 181 is completed. The build-up layer 40 is also prepared in the same technique.

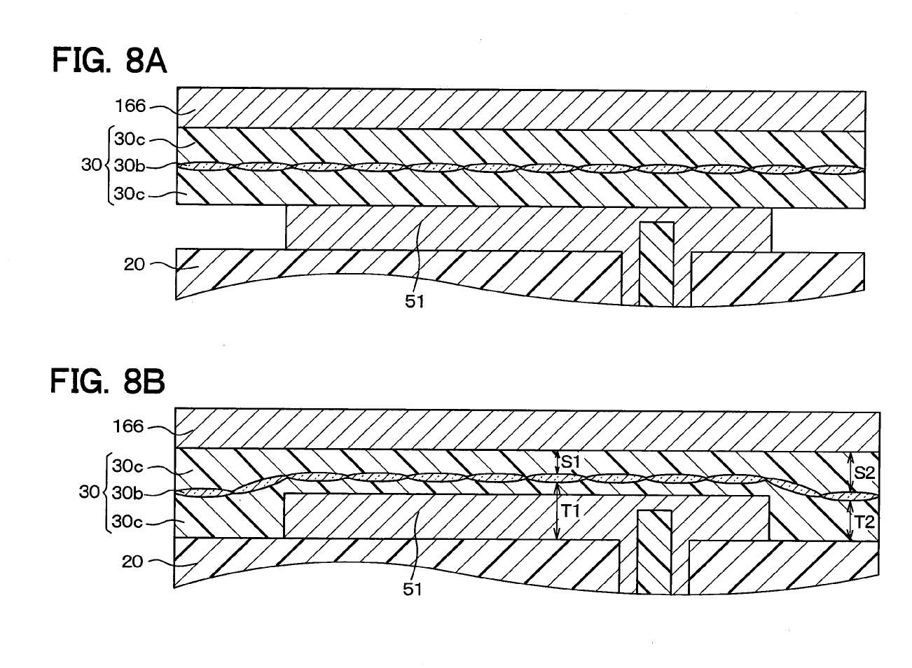

Further, the build-up layers 30 and 40 prepared in the above manner are disposed on both surfaces of the core layer 20 together with the metal plates 166 and 167, respectively, to configure the laminated body 168 as illustrated in FIG. 8A, and the laminated body 168 is heated while being pressurized in a laminating direction of the laminated body 168. With the above step, as illustrated in FIG. 5D, the build-up layer 30 is thermoset, and the laminated body 168 is integrated. Specifically, with the pressurization of the laminated body 168, a resin forming the resin layer 30c of the build-up layer 30 is allowed to flow, and embedded between the inner layer wires 51, and a resin forming the resin layer of the build-up layer 40 is allowed to flow, and embedded between the inner layer wires 52.

In this situation, since the inner layer wire 51 is disposed at a position to be formed with the land 61 on which the passive element 123 is mounted, the glass cloth 30b is extruded by the inner layer wire 51 together with the resin forming the resin layer 30c, and deformed in a direction away from the core layer 20, as illustrated in FIG. 8B. Further, the laminated body 168 is heated with the result that the build-up layers 30 and 40 are cured to integrate the laminated body 168. In this way, the laminated body 168 having the build-up layer 30 in which the glass cloth 30b is deformed toward the metal plate 166 can be configured. In this way, as illustrated in FIG. 5D, the integrated laminated body 168 is formed.

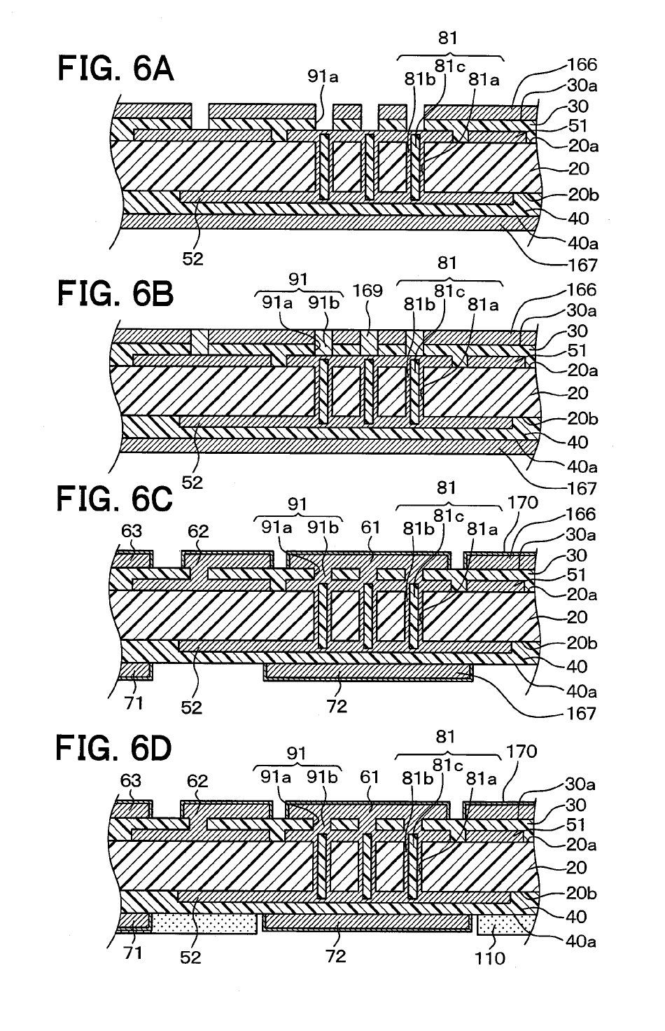

Then, as illustrated in FIG. 6A, through-holes 91a that penetrate through the metal plate 166 and the build-up layer 30, and reach the inner layer wire 51 are produced by laser. Likewise, in a cross-section different from that of FIG. 6A, through-holes 101a that penetrate through the metal plate 167 and the build-up layer 40, and reach the inner layer wire 52 are produced.

Further, as illustrated in FIG. 6B, a so-called filled plating is performed by the electroless plating or the electroplating, and the through-holes 91a and 101a are embedded with a metal plating 169. With the above process, a through-electrode 91b and a through-electrode 101b shown in FIG. 1 are formed by the metal plating 169 embedded in the through-holes 91a and 101a produced in the build-up layers 30 and 40, respectively. The filled vias 91 and 101 in which the through-holes 91a and 101a are embedded with the through-electrodes 91b and 101b, respectively, are produced. In FIG. 6C and the subsequent drawings, the metal plate 166 and the metal plating 169 are collectively illustrated as one layer.

Then, as illustrated in FIG. 6C, a resist not shown is disposed on the metal plates 166 and 167. Further, wet etching is performed with a resist as a mask to pattern the metal plates 166 and 167, and with the formation of a metal plating 170, the surface layer wires 61 to 63, and the surface layer wires 71, 72 are formed. In other words, in the present embodiment, the surface layer wires 61 to 63 are configured to have the metal plate 166 and the metal platings 169, 170, and the surface layer wires 71 and 72 are configured to have the metal plate 167 and the metal platings 169, 170. A metal film 64 in the surface layer wires 61 to 63 is configured by the metal plate 166, and a metal plating 65 is configured by the metal platings 169 and 170.

When the land 61 of the surface layer wires 61 to 63 is formed, for example, the electroless plating or the electroplating is performed in a state where a side surface 64c of the metal plate 166 forming the metal film 64 is covered with a mask with the result that the metal plating 65 is formed on only one surface 64a of the metal film 64.

Subsequently, as illustrated in FIG. 6D, the solder resist 110 is disposed on the respective surfaces 30a and 40a of the build-up layers 30 and 40, and appropriately patterned to manufacture the multi-layer substrate 10. In an area shown in FIG. 6D, all of the solder resist 110 on the surface 30a is removed, but the solder resist 110 is left in another region as illustrated in FIG. 1.

Thereafter, although not particularly shown, the electronic components 121 to 123 are mounted on the lands 61 through the solders 130. Wire bonding is performed between the power element 121 as well as the control element 122, and the lands 62, and the power element 121 and the control element 122 are electrically connected to the respective lands 62. Subsequently, the mold resin 150 is formed through the transfer mold technique or the compression mold technique using the mold so as to seal the lands 61, 62, and the electronic components 121 to 123. With the above process, the electronic device in which the mold resin 150 comes into close contact with a side surface 61c of each land 61 is manufactured.

As described above, in the present embodiment, the glass cloth 30b within the build-up layer 30 below the lands 61 is deformed toward the lands 61. The thickness S1 of the resin layer 30c from the glass cloth 30b to the surface adjacent to the land 61 is set to be smaller than the thickness (dimension) T1 from the glass cloth 30b to the core layer 20. With the above configuration, a progress or an enlargement of a crack can be suppressed from a stage in which the crack is smaller. Therefore, the progress and enlargement of the crack can be delayed. As such, even if the crack is generated, an insulating property between the land and an inner layer wire is ensured, and the land and the inner layer wire can be restricted from being short-circuited.

### Second Embodiment

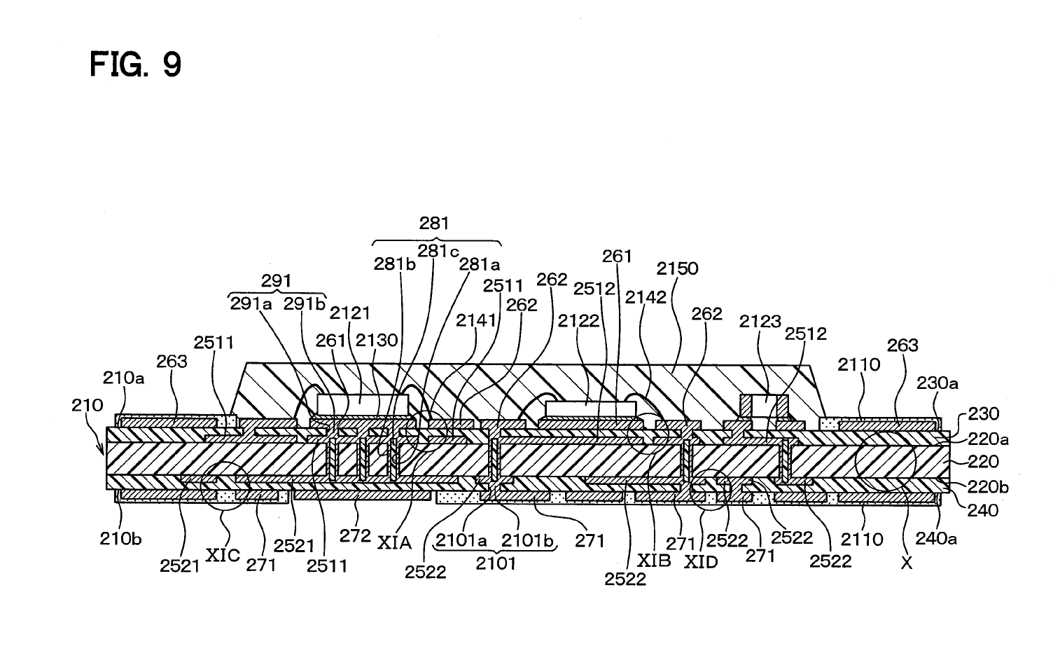

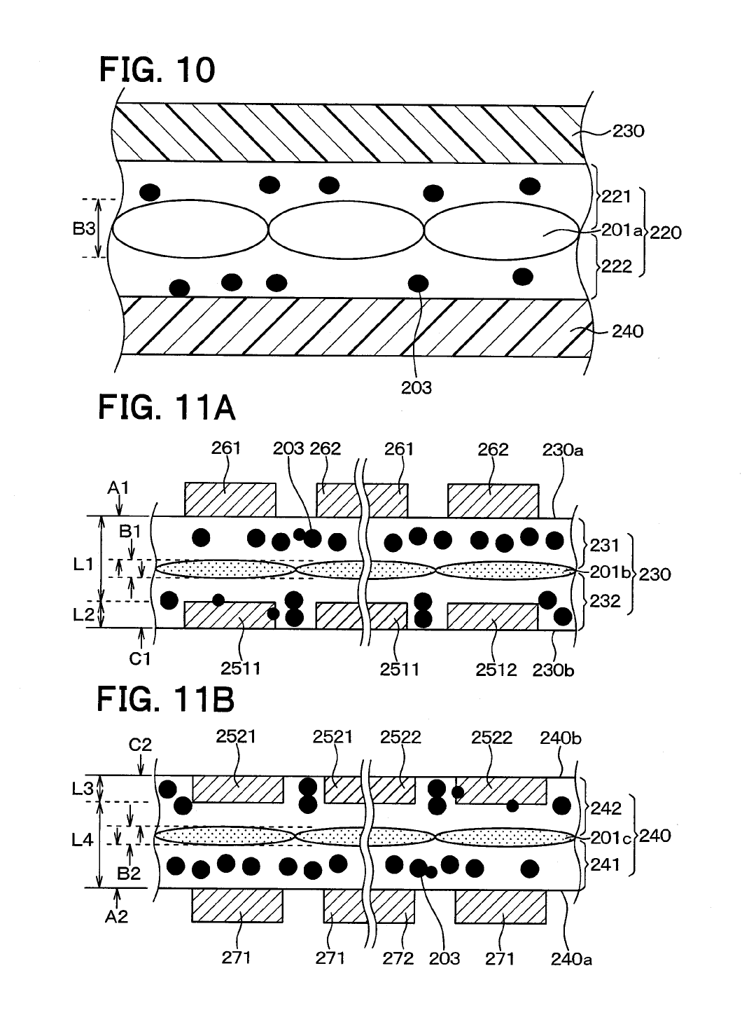

An electronic device according to a second embodiment of the present disclosure will be described with reference to FIGS. 9 and 10. The electronic device according to the present embodiment is also mounted on a vehicle such as an automobile, and applied for driving various electronic devices for the vehicle. In FIG. 10, a mold resin member 2150 and a solder resist 2110 are partially omitted.

As illustrated in FIG. 9, the electronic device includes a multi-layer substrate 210 having one surface 210a and the other surface 210b, and electronic components 2121 to 2123 mounted on the one surface 210a of the multi-layer substrate 210. A mold resin member 2150 in which the one surface 210a side of the multi-layer substrate 210 and the electronic components 2121 to 2123 are sealed with a mold resin to configure the electronic device.

The multi-layer substrate 210 is a laminated substrate including a core layer 220, a front surface side build-up layer 230 disposed on a front surface 220a of the core layer 220, and a rear surface side build-up layer 240 disposed on a rear surface 220b of the core layer 220.

The core layer 220 is configured as a prepreg layer made of prepreg. As illustrated in FIG. 10, the core layer 220 includes a glass cloth 201a, and resin layers 221, 222. The resin layer 221 is configured by sealing a surface of the glass cloth 201a adjacent to the build-up layer 230 with a resin material. The resin layer 222 is configured by sealing a surface of the glass cloth 201a adjacent to the build-up layer 240 with a resin material. A thermosetting resin material (for example, epoxy resin) having an electric insulating property is used as the resin material forming the resin layers 221 and 222. The resin material of the resin layers 221 and 222 is mixed with a filler 203 made of ceramic having an electric insulating property and a thermal conductivity and excellent in heat radiation such as alumina or silica.

The build-up layers 230 and 240 are each formed of a prepreg layer made of prepreg. As illustrated in FIG. 11A, the build-up layer 230 includes a glass cloth 201b and resin layers 231, 232. The resin layer 231 is configured by sealing a surface of the glass cloth 201b adjacent to front surface side surface layer wires 261 to 263 (only 261 and 262 are indicated in FIG. 11A) with a resin material. The resin layer 232 is configured by sealing a surface of the glass cloth 201b adjacent to front surface side inner layer wires 2511 and 2512 with a resin material. A thermosetting resin material (for example, epoxy resin) having an electric insulating property is used as the resin material forming the resin layers 231 and 232. The resin material of the resin layers 231 and 232 is mixed with the filler 203 made of ceramic having an electric insulating property and a thermal conductivity and excellent in heat radiation such as alumina or silica.

As illustrated in FIG. 11B, the build-up layer 240 includes a glass cloth 201c, and resin layers 241, 242. The resin layer 241 is configured by sealing a surface of the glass cloth 201c adjacent to rear surface side surface layer wires 271 and 272 (only 271 is indicated in FIG. 11B) with a resin material. The resin layer 242 is configured by sealing a surface of the glass cloth 201c adjacent to rear surface side inner layer wires 2521 and 2522 with a resin material.

A thermosetting resin material (for example, epoxy resin) having an electric insulating property is used as the resin material forming the resin layers 241 and 242. The resin material of the resin layers 241 and 242 is mixed with the filler 203 made of ceramic having an electric insulating property and a thermal conductivity and excellent in heat radiation such as alumina or silica. The glass clothes 201a, 201b, and 201c according to the present embodiment each have an electric insulating property.

The multiple front surface side inner layer wires 2511 and 2512 in FIG. 9 are formed on a front surface 220a of the core layer 220 between the core layer 220 and the build-up layer 230. Likewise, the multiple rear surface side inner layer wires 2521 and 2522 are formed on a rear surface 220b of the core layer 220 between the core layer 220 and the build-up layer 240. In other words, the multiple front surface side inner layer wires 2511 and 2512 are disposed in the build-up layer 230 adjacent to the core layer 220 in the thickness direction. The multiple rear surface side inner layer wires 2521 and 2522 are disposed in the build-up layer 240 adjacent to the core layer 220 in the thickness direction. The thickness direction represents a direction orthogonal to a direction along a surface of the build-up layer 230 (or 240).

The build-up layer 230 is laminated on the core layer 220 so as to cover the front surface 220a of the core layer 220 together with the multiple front surface side inner layer wires 2511 and 2512. The build-up layer 240 is laminated on the core layer 220 so as to cover the rear surface 220b of the core layer 220 together with the multiple rear surface side inner layer wires 2521 and 2522.

On the front surface 220a of the core layer 220, the resin layer 232 (refer to FIG. 11A) of the build-up layer 230 seals the multiple inner layer wires in a state where the resin layer 232 is filled between the adjacent two front surface side inner layer wires of the multiple front surface side inner layer wires 2511 and 2512. On the rear surface 220b of the core layer 220, the resin layer 242 (refer to FIG. 11B) of the build-up layer 240 seals the multiple inner layer wires in a state where the resin layer 242 is filled between the adjacent two rear surface side inner layer wires of the multiple rear surface side inner layer wires 2521 and 2522.

The multiple front surface side surface layer wires 261 to 263 are formed on the front surface 230a of the build-up layer 230. In other words, the multiple front surface side surface layer wires 261 to 263 are disposed on a side of the build-up layer 230 opposite to the core layer 220 in the thickness direction. In the present embodiment, the multiple front surface side surface layer wires 261 to 263 include mounting lands 261 on which electronic components 2121 to 2123 are mounted, bonding lands 262 that are electrically connected to the electronic components 2121 and 2122 through bonding wires 2141 and 2142, and a surface pattern 263 that is electrically connected to the external circuit.

Likewise, the multiple rear surface side surface layer wires 271 and 272 are formed on the surface 240a of the build-up layer 240. In other words, the multiple rear surface side surface layer wires 271 and 272 are disposed on a side of the build-up layer 240 opposite to the core layer 220 in the thickness direction. In the present embodiment, the multiple rear surface side surface layer wires 271 and 272 include a rear surface pattern 271 connected to the rear surface side inner layer wires 2521 and 2522 through a filled via to be described later, and a heat sink pattern 272 having a heat radiation heat sink.

The surface layer wires 261 to 263, 271, and 272 configure a first conductor. The inner layer wires 2511, 2512, 2521, and 2522 configure a second conductor. The front surface 230a of the build-up layer 230 means one surface of the build-up layer 230 adjacent to the front surface side surface layer wires 261 to 263, which is a surface forming the one surface 210a of the multi-layer substrate 210. The surface 240a of the build-up layer 240 means one surface of the build-up layer 240 adjacent to the rear surface side surface layer wires 271 and 272, which is a surface forming the other surface 210b of the multi-layer substrate 210.

The inner layer wires 2511, 2512, 2521, 2522, the front surface side surface layer wires 261 to 263, and the rear surface side surface layer wires 271 and 272 are conductors configured by appropriately laminating metal foils or metal platings made of copper on each other, which will be described in detail later.

The front surface side inner layer wires 2511, 2512 and the rear surface side inner layer wires 2521 and 2522 are electrically and thermally connected to each other through a through-via 281 that penetrates through the core layer 220. Specifically, the through-via 281 is configured in such a manner that a through-electrode 281b made of copper is formed on a wall surface of a through-hole 281a that penetrates through the core layer 220 in the thickness direction of the core layer 220, and an interior of the through-hole 281a is filled with a filler 281c.

The front surface side inner layer wires 2511 and 2512 as well as the front surface side surface layer wires 261 to 263, and the rear surface side inner layer wires 2521 and 2522 as well as the rear surface side surface layer wires 271 and 272 are electrically and thermally connected to each other through filled vias 291 and 2101 that appropriately penetrate through the build-up layers 230 and 240 in the thickness direction of those layers, respectively.

Specifically, the filled vias 291 and 2101 are configured in such a manner that through-holes 291a and 2101a that penetrate through the build-up layers 230 and 240 in the thickness direction are filled with through-electrodes 291b and 2101b made of copper or the like.

The filler 281c is made of resin, ceramic, or metal, and made of epoxy resin in the present embodiment. The through-electrodes 281b, 291b, and 2101b are made of metal plating made of copper or the like.

The surfaces 230a and 240a of the respective build-up layers 230 and 240 are formed with a solder resist 2110 that covers the front surface pattern 263 and the rear surface pattern 271. An opening is defined in the solder resist 2110 that covers the front surface pattern 263 in a cross-section different from that in FIG. 9. The opening exposes a portion of the front surface pattern 263 which is connected to the external circuit.

The electronic components 2121 to 2123 include a power element 2121 large in heat generation such as an IGBT (insulated gate bipolar transistor) or an MOSFET (metal oxide semiconductor field effect transistor), a control element 2122 such as a microcomputer, and a passive element 2123 such as a chip capacitor or a resistor.

The respective electronic components 2121 to 2123 are mounted on the lands 261 through solders 2130, and electrically and mechanically connected to the lands 261. The power element 2121 and the control element 2122 are also electrically connected to the lands 262 formed around the power element 2121 and the control element 2122 through the bonding wires 2141 and 2142 made of Al, Au or the like.

In this example, the above-mentioned first wiring groups 2511 and 2521 are the front and rear inner layer wires 2511 and 2521 connected to the power element 2121 of a relatively large current. On the other hand, the above-mentioned second wiring groups 2512 and 2522 are the front and rear inner layer wires 2512 and 2522 connected to the control element 2122 and the passive element 2123 of a relatively small current.

In this example, the electronic components 2121 to 2123 are exemplified by the power element 2121, the control element 2122, and the passive element 2123, but the electronic components 2121 to 2123 are not limited to those components.

The mold resin member 2150 is configured to seal the lands 261, 262, and the electronic components 2121 to 2123, and formed with general mold material such as epoxy resin through a transfer mold technique or a compression mold technique using a mold.

In the present embodiment, the mold resin 2150 is formed on only the one surface 210a of the multi-layer substrate 210. In other words, the electronic device according to the present embodiment is of a so-called half-mold structure. On the other surface 210b side of the multi-layer substrate 210, a heat sink is disposed on the heat sink pattern 272 through a heat radiation grease although not particularly shown.

Subsequently, a structure of the build-up layers 230 and 240 according to the present embodiment will be described in detail with reference to FIGS. 11A and 11B.

It is assumed that a dimension between the front surface side surface layer wires 261 to 263 (that is, the front surface 230a of the build-up layer 230) and the glass cloth 201b is A1 in the thickness direction of the build-up layer 230 in FIG. 11A. The dimension A1 according to the present embodiment represents the shortest distance between the front surface side surface layer wires 261 to 263 and the glass cloth 201b. It is assumed that a thickness (that is, a dimension of the glass cloth 201b in the thickness direction between the surface adjacent to the front surface side surface layer wires 261 to 263 and the surface adjacent to the front surface side inner layer wires 2511 and 2512) of the glass cloth 201b is B1. It is assumed that a dimension in the thickness direction between the rear surface 230b (that is, the surface of the build-up layer 230 adjacent to the front surface side inner layer wires 2511 and 2512) and the glass cloth 201b is C1. The dimension C1 according to the present embodiment represents the shortest distance between the rear surface 230b of the build-up layer 230 and the glass cloth 201b. A1, B1, and C1 satisfy a size relationship of C1>A1>B1.

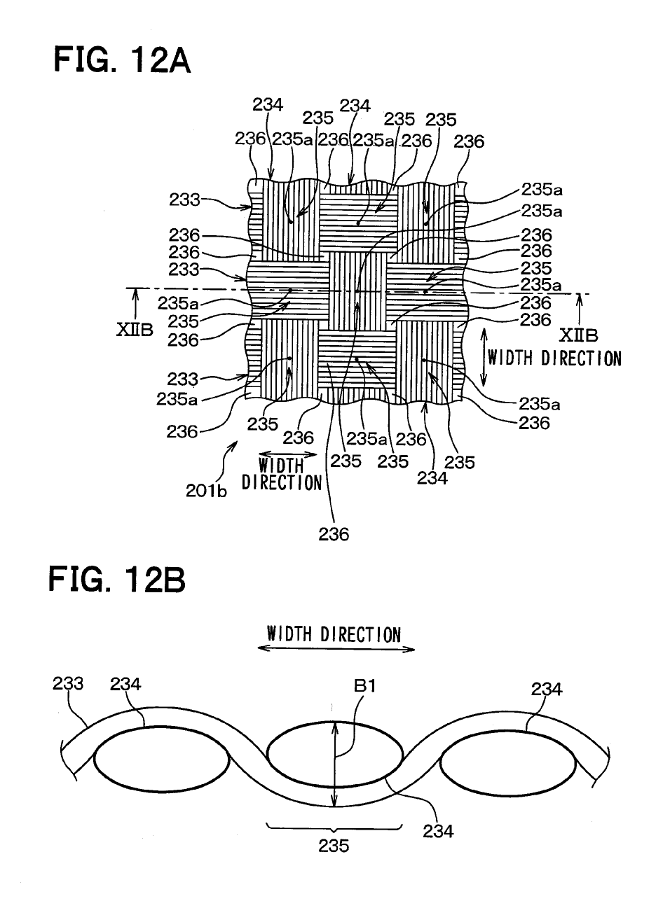

In the present embodiment, a reference position of the glass cloth 201b for setting the dimension A1 is set to an upper end of the glass cloth 201b. A reference position of the glass cloth 201b for setting the dimension C1 is set to a lower end of the glass cloth 201b. Hereinafter, the upper end and the lower end of the glass cloth 201b will be described. FIG. 12A is a partially enlarged view of the glass cloth 201b viewed from the side of the front surface side surface layer wires 261 to 263.

As illustrated in FIG. 12A, the glass cloth 201b includes multiple horizontal yarns 233 and multiple vertical yarns 234, and has multiple bellies 235 and multiple basket halls 236. The horizontal yarns 233 are configured by bundling multiple glass fibers extending in a horizontal direction. The vertical yarns 234 are configured by bundling multiple glass fibers extending in a vertical direction. The multiple bellies 235 are portions where the horizontal yarns 233 and the vertical yarns 234 overlap with each other. The multiple basket halls 236 are holes surrounded by the adjacent two horizontal yarns 233 of the multiple horizontal yarns 233 and the adjacent two vertical yarns 234 of the multiple vertical yarns 234. FIG. 12A shows nine bellies 235 and sixteen basket halls 236.

Each of the vertical yarns 234 is largest in the thickness of a center of the vertical yarn 234 in a width direction (refer to FIG. 12B). Likewise, each of the yarns 233 is largest in the thickness of a center of the vertical yarn 234 in the width direction. FIG. 12B is an enlarged cross-sectional view taken along a line XIIB-XIIB in FIG. 12A. A planar center portion 235a of the bellies 235 of the glass cloth 201b is largest in the thickness. The planar center portion 235a is a portion where a center portion of the horizontal yarn 233 in the width direction overlaps with a center portion of the vertical yarn 234 in the width direction.

Under the circumstances, in the present embodiment, the planar center portion 235a of the bellies 235 adjacent to the front surface side surface layer wires 261 to 263 in the multiple bellies 235 of the glass cloth 201b is set to an upper end of the glass cloth 201b. The planar center portion 235a of the bellies 235 adjacent to the front surface side inner layer wires 2511 and 2512 in the multiple bellies 235 of the glass cloth 201b is set to a lower end of the glass cloth 201b. It is assumed that a thickness of the planar center portion 235a (refer to FIG. 12B) of the bellies 235 in the glass cloth 201b is a dimension B1.

It is assumed that a dimension between the rear surface side surface layer wires 271, 272 (that is, the surface 240a of the build-up layer 240) and the glass cloth 201c is A2 in the thickness direction of the build-up layer 240 in FIG. 11B. The dimension A2 according to the present embodiment represents the shortest distance between the rear surface side surface layer wires 271, 272 and the glass cloth 201c. It is assumed that a thickness (that is, a dimension of the glass cloth 201c between a surface adjacent to the rear surface side surface layer wires 271 to 272 and a surface adjacent to the rear surface side inner layer wires 2521 and 2522) of the glass cloth 201c is B2. It is assumed that a dimension in the thickness direction between the rear surface 240b (that is, a surface of the build-up layer 240 adjacent to the rear surface side inner layer wires 2521 and 2522) and the glass cloth 201c is C2. The dimension C2 according to the present embodiment represents the shortest distance between the rear surface 240b of the build-up layer 240 and the glass cloth 201c. A2, B2, and C2 satisfy a size relationship of C2>A2>B2.

In this example, the dimension A2 is a dimension between a lower end of the glass cloth 201c and the rear surface side surface layer wires 271, 272. The lower end of the glass cloth 201c represents the planar center portion of the bellies adjacent to the rear surface side surface layer wires 271 and 272 in the multiple bellies of the glass cloth 201c. The planar center portion of the bellies represents a portion of the belly largest in the thickness as described above. The dimension C2 is a dimension of the glass cloth 201c between an upper end of the glass cloth 201c and the rear surface side inner layer wires 2521, 2522. The upper end of the glass cloth 201c represents the planar center portion of the bellies adjacent to the rear surface side inner layer wires 2521 and 2522 in the multiple bellies of the glass cloth 201c. A thickness of the planar center portion 235a of the bellies 235 in the glass cloth 201c is set as a dimension B2.

In the build-up layer 230 according to the present embodiment, when a crack is generated in the resin layer 231, the crack may progress to the resin layer 232 through the basket halls 236 of the glass cloth 201b (or between the multiple glass fibers configuring the multiple horizontal yarns 233 and the multiple vertical yarns 234). On the contrary, the glass cloth 201b is woven with the multiple horizontal yarns 233 and the multiple vertical yarns 234. For that reason, when the crack generated in the resin layer 231 progresses to the resin layer 232, the multiple glass fibers configuring the multiple horizontal yarns 233 or the multiple vertical yarns 234 have the bridge effect of reducing the progress rate at which the crack progresses in the resin layer 232. In other words, when the crack generated in the resin layer 231 progresses to the resin layer 232, the glass cloth 201b has the bridge effect of reducing the progress rate at which the crack progresses in the resin layer 232. The progress rate represents a rate at which the crack progresses towards the rear surface 230b from the glass cloth 201b.

The glass cloth 201c is woven with the multiple horizontal yarns 233 and the multiple vertical yarns 234 as with the glass cloth 201b. For that reason, when the crack generated in the resin layer 241 progresses to the resin layer 242, the glass cloth 201c has the bridge effect of reducing the progress rate at which the crack progresses in the resin layer 242. The progress rate represents a rate at which the crack progresses toward the rear surface 240b from the glass cloth 201c.

A dimension L1 (refer to FIG. 11A) between the front surface 230a of the build-up layer 230 and the surface of the front surface side inner layer wires 2511 and 2512 adjacent to the glass cloth 201b is set to 20 μm to 150 μm. A dimension L4 (refer to FIG. 11B) between the surface 240a of the build-up layer 240 and the surface of the rear surface side inner layer wires 2521 and 2522 adjacent to the glass cloth 201c is set to 20 μm to 150 μm. A thickness L2 of the front surface side inner layer wires 2511 and 2512 (refer to FIG. 11A) is set to 30 μm to 170 μm. A thickness L3 (refer to FIG. 11B) of the rear surface side inner layer wires 2521 and 2522 is set to 30 μm to 170 μm.

The dimensions A1 and A2 of the present embodiment are set to 20 μm to 100 μm, the dimensions B1 and B2 are set to 10 μm to 30 μm, and the dimensions C1 and C2 are set to 45 μm to 160 μm.

In the present embodiment, a rate (wt %) of the mass of the resin material to the mass of the build-up layers 230 and 240 is larger than a rate (wt %) of the mass of the resin material to the mass of the core layer 220. Specifically, the rate (wt %) of the mass of the resin material to the mass of the build-up layers 230 and 240 is equal to or larger than 80%.

The thicknesses (dimensions B1 and B2 in FIG. 11) of the glass clothes 201b and 201c of the build-up layers 230 and 240 are smaller than the thickness (dimension B3 in FIG. 10) of the glass cloth 201a of the core layer 220.

In the present embodiment, the thickness of the planar center portion in any one belly of the multiple bellies configuring the glass cloth 201a is set as the thickness of the glass cloth 201a. The thicknesses of the glass clothes 201b and 201c of the build-up layers 230 and 240 are set to 10 μm to 30 μm. A rate (wt %) of the mass of the filler 203 to the mass of the build-up layers 230 and 240 is larger than a rate (wt %) of the mass of the filler 203 to the mass of the core layer 220. The rate of the filler 203 to the build-up layers 230 and 240 is set for ensuring the sufficient thermal conductivities of the build-up layers 230 and 240.

The thicknesses of the glass clothes 201b and 201c are set for keeping a constant thermal conductivity or higher while ensuring a strength for preventing the glass clothes 201b and 201c from being broken. The glass clothes 201b and 201c having the thermal conductivity of 0.5 to 0.8 (W/m·k) are used.

The linear expansion coefficient of the resin layers 231 and 232 of the build-up layer 230 is set to be smaller than the linear expansion coefficient of the wires 2511, 2512, 2521, 2522, and 261 to 263. The linear expansion coefficient of the resin layers 240a and 240b of the build-up layer 240 is set to be smaller than the linear expansion coefficient of the wires 2511, 2512, 2521, 2522, 271, and 272. The linear expansion coefficient represents a rate at which a length of an object expands due to an increase in the temperature.

The linear expansion coefficient of the resin material (for example, epoxy resin) configuring the resin layers 231, 232, 241, and 242 according to the present embodiment is set to be larger than the linear expansion coefficient of the wires 2511, 2512, 2521, 2522, 261 to 263, 271, and 272. The linear expansion coefficient of the filler 203 configuring the resin layers 231, 232, 241, and 242 is smaller than the linear expansion coefficient of the resin material. The linear expansion coefficient of the resin layers 231 and 232 is set by regulating the rate of the filler 203 contained in the resin layers 231 and 232. The linear expansion coefficient of the resin layers 241 and 242 is set by regulating the rate of the filler 203 contained in the resin layers 241 and 242.

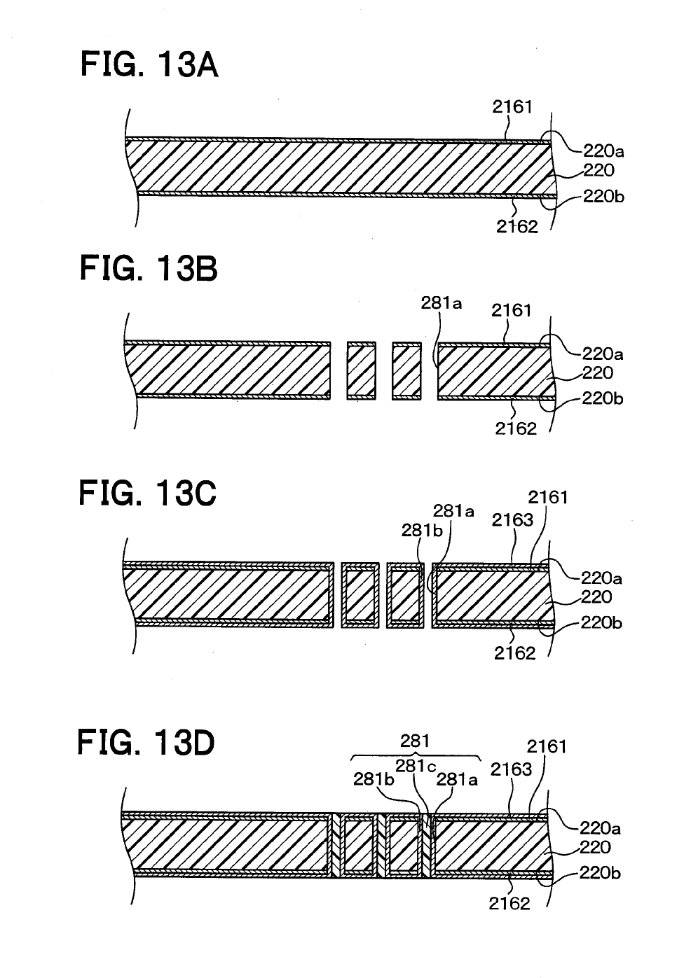

The configuration of the electronic device according to the present embodiment is described above. Subsequently, a method of manufacturing the above electronic device will be described with reference to FIGS. 13A to 13D, 14A to 14D, and 15A to 15D. FIGS. 13A to 13D, 14A to 14D, and 15A to 15D are cross-sectional views of the neighborhood of a portion of the multi-layer substrate 210 on which the power element 2121 is mounted.

First, as illustrated in FIG. 13A, a structure in which metal foils 2161 and 2162 such as copper foils are disposed on the front surface 220a and the rear surface 220b of the core layer 220 is prepared. Further, as illustrated in FIG. 13B, the through-holes 281a that penetrate through the metal foil 2161, the core layer 220, and the metal foil 2162 are produced by a drill.

Thereafter, as illustrated in FIG. 13C, electroless plating or electroplating is performed to form a metal plating 2163 made of copper on wall surfaces of the through-holes 281a, and the metal foils 2161, 2162. With the above process, through-electrodes 281b formed of the metal plating 2163 are formed on the wall surfaces of the respective through-holes 281a. It is preferable that the electroless plating and the electroplating are performed with the use of catalyst such as palladium.

Subsequently, as illustrated in FIG. 13D, the filler 281c is disposed in spaces surrounded by the metal plating 2163. With this process, the through-vias 281 each having the through-hole 281a, the through-electrode 281b, and the filler 281c are produced.

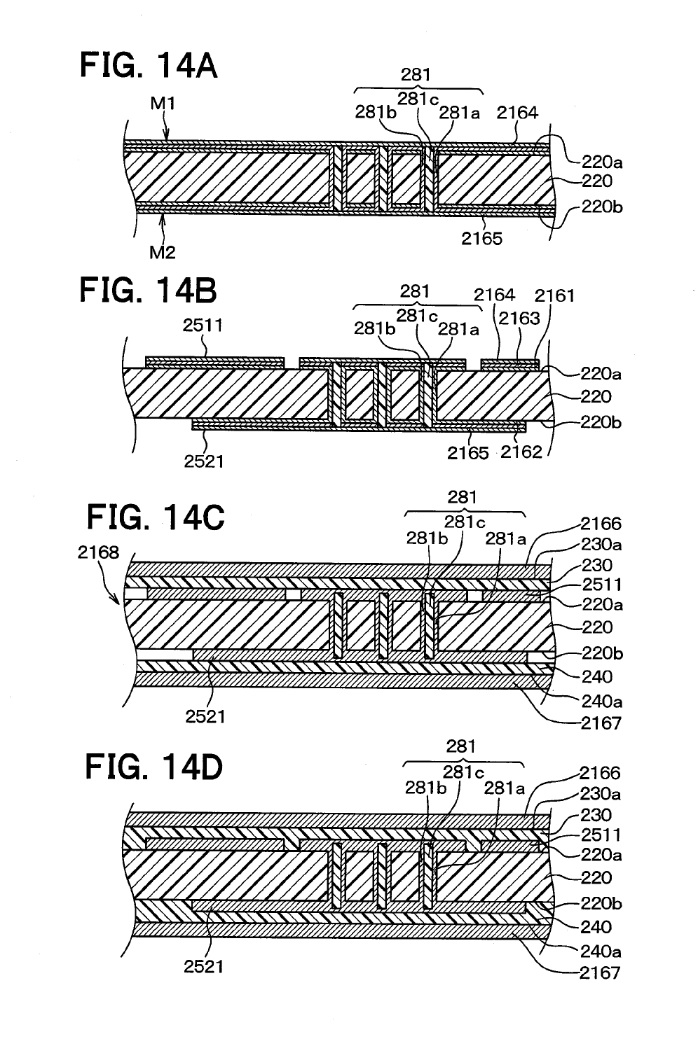

Thereafter, as illustrated in FIG. 14A, a so-called cover plating is performed by the electroless plating and the electroplating to form metal platings 2164 and 2165 made of copper on the metal plating 2163 and the filler 281c.

In this way, as illustrated in FIG. 14A, a metal layer M1 in which the metal foil 2161, the metal plating 2163, and the metal plating 2164 are sequentially laminated on each other is formed on the front surface 220a side of the core layer 220, and a metal layer M2 in which the metal foil 2162, the metal plating 2163, and the metal plating 2165 are sequentially laminated on each other is formed on the rear surface 220b side.

Then, as illustrated in FIG. 14B, a resist not shown is disposed on the metal platings 2164 and 2165. Further, wet etching is performed with the resist as a mask, and the metal plating 2164, the metal plating 2163, and the metal foil 2161 are appropriately patterned to form the front surface side inner layer wires 2511 and 2512. The metal plating 2165, the metal plating 2163, and the metal foil 2162 are appropriately patterned to form the rear surface side inner layer wires 2521 and 2522.

In other words, in the present embodiment, the front surface inner layer wires 2511 and 2512 are configured by the metal layer M1 in which the metal foil 2161, the metal plating 2163, and the metal plating 2164 are laminated on each other, and the rear surface side inner layer wires 2521 and 2522 are configured by the metal layer M2 in which the metal foil 2162, the metal plating 2163, and the metal plating 2165 are laminated on each other. In FIG. 14C and the subsequent drawings, the metal foil 2161, the metal plating 2163, and the metal plating 2164 as well as the metal foil 2162, the metal plating 2163, and the metal plating 2165 are collectively illustrated as one layer.

Thereafter, as illustrated in FIG. 14C, the build-up layer 230 and a metal plate 2166 made of copper are laminated on the front surface side inner layer wires 2511 and 2512 on the front surface 220a the core layer 220. The build-up layer 240 and a metal plate 2167 made of copper are laminated on the rear surface side inner layer wires 2521 and 2522 on the rear surface 220b of the core layer 220.

In the above manner, a laminated body 2168 in which the metal plate 2166, the build-up layer 230, the front surface side inner layer wires 2511, 2512, the core layer 220, the rear surface side inner layer wires 2521, 2522, the build-up layer 230, and the metal plate 2167 are laminated on each other in order from the top is configured. Incidentally, the build-up layers 230 and 240 are temporarily cured, and have a fluidity in this state.

Subsequently, as illustrated in FIG. 14D, the laminated body 2168 is heated while being pressurized from the laminating direction of the laminated body 2168, thereby being integrated. Specifically, the resin material configuring the build-up layers 230 and 240 is allowed to flow with the pressurization of the laminated body 2168. The resin material configuring the build-up layer 230 is embedded between the adjacent two front surface side inner layer wires of the multiple front surface side inner layer wires 2511 and 2512. At the same time, the resin material configuring the build-up layer 240 is embedded between the adjacent two rear surface side inner layer wires of the multiple rear surface side inner layer wires 2521 and 2522. Further, with the heating of the laminated body 2168, the build-up layers 230 and 240 are cured to integrate the laminated body 2168.

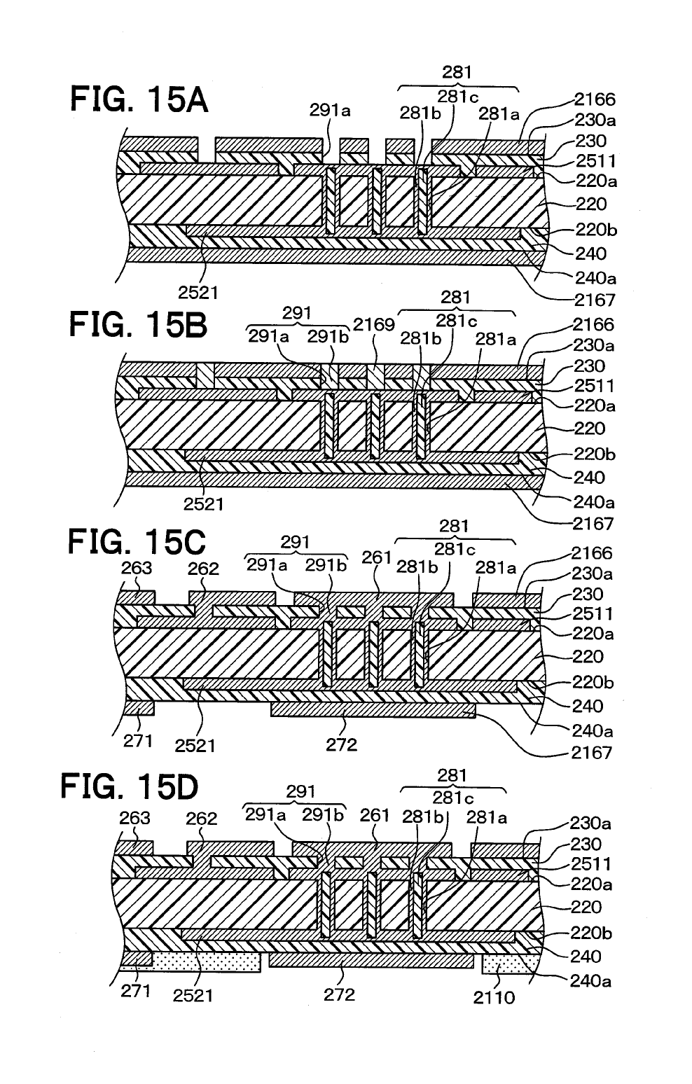

Then, as illustrated in FIG. 15A, through-holes 291a that penetrate through the metal plate 2166 and the build-up layer 230, and reach the front surface side inner layer wires 2511 and 2512 are produced by laser. Likewise, in a cross-section different from that of FIG. 15A, through-holes 2101a that penetrate through the metal plate 2167 and the build-up layer 240, and reach the rear surface side inner layer wires 2521 and 2522 are produced.

Further, as illustrated in FIG. 15B, a so-called filled plating is performed by the electroless plating or the electroplating, and the through-holes 291a and 2101a are embedded with a metal plating 2169. With the above process, a through-electrode 291b and a through-electrode 2101b shown in FIG. 9 are formed by the metal plating 2169 embedded in the through-holes 291a and 2101a produced in the build-up layer 230. The filled vias 291 and 2101 in which the through-holes 291a and 2101a are embedded with the through-electrodes 291b and 2101b, respectively, are produced. In FIG. 15C and the subsequent drawings, the metal plate 2166 and the metal plating 2169 are collectively illustrated as one layer.

Then, as illustrated in FIG. 15C, a resist not shown is disposed on the metal platings 2166 and 2167. Further, wet etching is performed with a resist as a mask to pattern the metal plates 2166 and 2167, and with the appropriate formation of a metal plating, the front surface side surface layer wires 261 to 263, and the rear surface side surface layer wires 271, 272 are formed.

In other words, in the present embodiment, the front surface side surface layer wires 261 to 263 are configured to have the metal plate 2166 and the metal plating 2169, and the rear surface side surface layer wires 271 and 272 are configured to have the metal plate 2167 and the metal plating 2169.

Subsequently, as illustrated in FIG. 15D, the solder resist 2110 is disposed on the respective surfaces 230a and 240a of the build-up layers 230 and 240, and appropriately patterned to manufacture the multi-layer substrate 210. In an area shown in FIG. 15D, all of the solder resist 2110 on the front surface 230a is removed, but the solder resist 2110 is left in another region as illustrated in FIG. 9.

Thereafter, although not particularly shown, the electronic components 2121 to 2123 are mounted on the lands 261 through the solders 2130. Wire bonding is performed between the power element 2121 as well as the control element 2122, and the lands 262, and the power element 2121 and the control element 2122 are electrically connected to the respective lands 262. Subsequently, the mold resin member 2150 is formed through the transfer mold technique or the compression mold technique using the mold so as to seal the lands 261, 262, and the electronic components 2121 to 2123.

According to the present embodiment described above, in the multi-layer substrate 210, the front surface side surface layer wires 261 to 263 are disposed on one side of the build-up layer 30 in the thickness direction (that is, the front surface 230a side). The front surface side inner layer wires 2511 and 2512 are disposed on the other side of the build-up layer 230 in the thickness direction (that is, the rear surface 230b side). The rear surface side surface layer wires 271 and 272 are disposed on one side of the build-up layer 240 in the thickness direction (that is, the front surface 240a side). The rear surface side inner layer wires 2521 and 2522 are disposed on the other side of the build-up layer 240 in the thickness direction (that is, the rear surface 240b side). The linear expansion coefficient of the resin layers 231 and 241 of the build-up layers 230 and 240 is lower than the linear expansion coefficient of the surface layer wires 261 to 263, 271, and 272, and the linear expansion coefficient of the glass clothes 201b and 201c is lower than the linear expansion coefficient of the resin layers 231 and 241. It is assumed that a dimension in the thickness direction between the front surface side surface layer wires 261 to 263 and the glass cloth 201b is A1, a thickness of the glass cloth 201b is B1, and a dimension between the rear surface 230b (that is, a surface on the front surface side inner layer wires 2511 and 2512 side) of the build-up layer 230 and the glass cloth 201b is C1. In this case, A1, B1, and C1 satisfy a size relationship of C1>A1>B1.

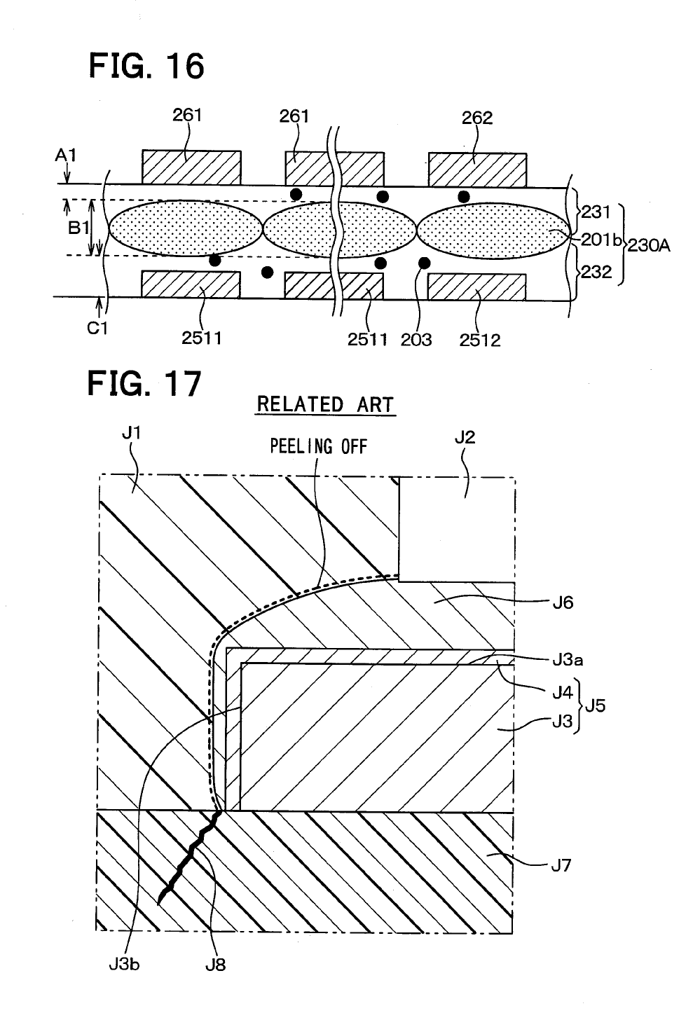

With the above configuration, in the build-up layer 230, the size relationship of A1>B1 is satisfied. Therefore, in the build-up layers 230 and 1230A having the same thickness (refer to FIG. 16), the build-up layer 230 can increase a distance between the front surface side surface layer wires 261 to 263 and the glass cloth 201b as compared with the build-up layer 1230A that satisfies the size relationship of A1<B1 with the use of the glass cloth 201b large in the thickness. Therefore, an influence of the linear expansion coefficient of the glass cloth 201b can be reduced as compared with the linear expansion coefficient of the build-up layer 230 adjacent to the front surface side surface layer wires 261 to 263.

The linear expansion coefficient of the build-up layer 230 on the front surface side surface layer wires 261 to 263 side represents a rate at which a length of the build-up layer 230 on the front surface side surface layer wires 261 to 263 side changes due to an increase in the temperature. For that reason, when a distance between the front surface side surface layer wires 261 to 263 and the glass cloth 201b is set to be larger, a difference between the linear expansion coefficient of the build-up layer 230 on the front surface side surface layer wires 261 to 263 side and the linear expansion coefficient of the front surface side surface layer wires 261 to 263 can be reduced. For that reason, an internal stress can be restricted from being generated due to a change in the temperature on the interface between the build-up layer 230 and the front surface side surface layer wires 261 to 263. As a result, the crack (that is, a first conductor side starting point crack) can be restricted from being generated in the resin layer 231 due to the internal stress caused by the change in the temperature.

It is assumed that a dimension between the rear surface side surface layer wires 271, 272 and the glass cloth 201c in the build-up layer 240 is A2, and a thickness of the glass cloth 201c is B2. When it is assumed that a dimension between the surface 240b (that is, the rear surface side inner layer wires 2521 and 2522 side) of the build-up layer 240 and the glass cloth 201c is C2, A2, B2, and C2 satisfy the size relationship of C2>A2>B2.

As described above, in the build-up layer 240, the size relationship of A2>B2 is satisfied. For that reason, as with the build-up layer 230, as compared with a case in which the size relationship of A2<B2 is satisfied when the thickness of the build-up layer 240 is kept constant, an influence of the linear expansion coefficient of the glass cloth 201c can be reduced more than the linear expansion coefficient of the build-up layer 240 adjacent to the rear surface side surface layer wires 271 and 272.

The linear expansion coefficient of the build-up layer 240 adjacent to the rear surface side surface layer wires 271 and 272 represents a rate at which a length of the build-up layer 240 adjacent to the rear surface side surface layer wires 271 and 272 changes due to an increase in the temperature.

Therefore, when the size relationship of A2>B2 is satisfied in the build-up layer 240, the crack (that is, a first conductor side starting point crack) can be restricted from being generated in the resin layer 241 due to the internal stress caused by the change in the temperature, in the interface between the build-up layer 240 and the rear surface side surface layer wires 271, 272.

In the present embodiment, the size relationship of C1>A1 is satisfied. For that reason, as compared with a case in which the size relationship of A1>C1 is satisfied when the thickness of the build-up layer 230 is kept constant, a thickness of a region in which the progress rate of the crack is reduced due to the bridge effect of the glass cloth 201b becomes large. For that reason, when the crack generated by the internal stress progresses to the resin layer 232 from the resin layer 231 in the interface between the build-up layer 230 and the front surface side surface layer wires 261 to 263, a time required for the crack to progress to the rear surface 230b in the resin layer 232 is lengthened. Therefore, the strength of the overall build-up layer 230 against the crack (that is, the first conductor side starting point crack) generated by the internal stress can be improved.

In the present embodiment, the size relationship of C2>A2 is satisfied. For that reason, as compared with a case in which the size relationship of A2>C2 is satisfied when the thickness of the build-up layer 240 is kept constant, a thickness of a region in which the progress rate of the crack is reduced due to the bridge effect of the glass cloth 201c becomes large. For that reason, when the crack generated by the internal stress progresses to the resin layer 242 from the resin layer 241 in the interface between the build-up layer 240 and the rear surface side surface layer wires 271 to 272, a time required for the crack to progress to the rear surface 240b in the resin layer 242 is lengthened. Therefore, the strength of the overall build-up layer 240 against the crack (that is, the first conductor side starting point crack) generated by the internal stress can be improved.

With the above configuration, the multi-layer substrate 210 and the electronic device that perform both of the suppression of the generation of the crack (first conductor side starting point crack) generated by the internal stress and an improvement in the strength of the overall build-up layer 230 (240) against the crack can be provided.

In the present embodiment, if the crack is generated in the resin layer 231 of the build-up layer 230, there is a risk that the internal stress is generated in the resin layer 232 due to the crack of the resin layer 231, and the crack is generated in the resin layer 232. On the contrary, the build-up layer 230 satisfies the size relationship of C1>A1. For that reason, the strength of the resin layer 232 becomes large as compared with the build-up layer 230A (refer to FIG. 16) that satisfies the size relationship of A1>C1. As a result, the crack can be restricted from being generated in the resin layer 232 due to the crack of the resin layer 231.

In the build-up layer 240, the size relationship of C2>A2 is satisfied. For that reason, if the crack is generated in the resin layer 241 of the build-up layer 240, the crack can be restricted from being generated in the resin layer 242 due to the crack of the resin layer 241 as with the build-up layer 230. With the above configuration, the crack can be restricted from being generated in the multi-layer substrate 210.

In addition, the build-up layer 230 satisfies the size relationship of C1>A1. Hence, when the crack is generated in the resin layer 231 in the thickness direction, as compared with the build-up layer 230 that satisfies the size relationship of A1>C1, the build-up layer 230 according to the present embodiment can reduce the dimension of the crack in the resin layer 231 in the thickness direction. Hence, a reduction in the electric insulating property of the build-up layer 230 due to the crack can be suppressed. Likewise, the build-up layer 240 according to the present embodiment satisfies the size relationship of C2>A2. A reduction in the electric insulating property of the build-up layer 240 due to the crack can be suppressed. With the above configuration, a reduction in the electric insulating property of the multi-layer substrate 210 due to the crack can be suppressed.

### OTHER EMBODIMENTS

The present disclosure is not limited to the above embodiments, but can appropriately change within a scope of the claims.

For example, in the above first embodiment, in particular, the surroundings of the land 61 on which the passive element 123 is mounted are exemplified as a location where the crack is liable to be generated. The same is applied to the lands 61 on which the power element 121 or the control element 122 other than the passive element 123 is mounted. Therefore, the same advantages as those in the above embodiment can be obtained by deforming the glass cloth 30b within the build-up layer 30 toward the land 61 side at a position below the land 61 on which the power element 121 or the control element 122 is mounted.

In the above first embodiment, as an extrusion member for pushing up the glass cloth 30b toward the land 61 side, the inner layer wire 51 disposed below the land 61 is used. Alternatively, a member different from the inner layer wire 51, for example, a protruded member used only for extruding the glass cloth 30b, that is, a structure protruded from the front surface of the core layer 20 may be disposed as the extrusion member. For example, the structure forming the extrusion member can be made of resin. However, if the inner layer wire 51 is used as the extrusion member, because there is no need to provide the structure used only for extrusion of the glass cloth 30b, the manufacturing process can be simplified.

In the above respective embodiments, the core layer 20 and the build-up layers 30, 40 are each formed of a single layer of prepreg. Alternatively, the core layer 20 and the build-up layers 30, 40 may be each formed of multiple layers of prepreg.

In the above second embodiment, an example using the core layer 220 formed of the prepreg layer is described. Alternatively, the insulating layer may be formed of the core layer 220 made of ceramic.

In the second embodiment, the example in which the linear expansion coefficient of the respective resin layers 231 and 241 of the build-up layers 230 and 240 is set to be lower than the linear expansion coefficient of the surface layer wires 261 to 263, 271, and 272 is described. Alternatively, the linear expansion coefficient of the respective resin layers 231 and 241 of the build-up layers 230 and 240 may be set to be higher than the linear expansion coefficient of the surface layer wires 261 to 263, 271, and 272.

In the above second embodiment, the example in which the dimensions A1, B1, and C1 satisfy the size relationship of C1>A1>B1 is described. Alternatively, the dimensions A1, B1, and C1 may be set to satisfy the size relationship of C1≧A1≧B1. Alternatively, the dimensions A1, B1, and C1 may be set to satisfy the size relationship of C1>A1≧B1 or C1≧A1>B1.

In the above second embodiment, the example in which the dimensions A2, B2, and C2 satisfy the size relationship of C2>A2>B2 is described. Alternatively, the dimensions A2, B2, and C2 may be set to satisfy any one of the size relationships of C2>A2≧B2, C2≧A2>B2, and C2≧A2≧B2.

As described above, the present disclosure is not limited to the above embodiments, but can appropriately change without departing from a scope of the claims. The above respective embodiments are not irrelevant to each other, and can be appropriately combined with each other except that the combination is clearly improper, and the respective embodiments are not limited to the above illustrated examples.

1. A multi-layer substrate comprising:
a core layer having a front surface;
an inner layer wire disposed on the front surface of the core layer;
a build-up layer arranged on the front surface of the core layer in a state where the build-up layer covers the inner layer wire, the build-up layer including a glass cloth woven with glass fibers into a film shape, and a resin layer that covers both of front and rear surfaces of the glass cloth; and
a land disposed on a surface of the build-up layer opposite to the core layer, over which an electronic component is to be mounted through a solder, wherein
the glass cloth is extruded toward the land in a portion of the build-up layer, the portion being located between the land and the core layer, and a thickness of the resin layer from the glass cloth to the surface of the resin layer adjacent to the land is smaller than a dimension from the glass cloth to the front surface of the core layer in the portion.

2. The multi-layer substrate according to claim 1, wherein
in a portion of the build-up layer outside of the land, a thickness of the resin layer from the glass cloth to the surface of the resin layer adjacent to the land is equal to a thickness of the resin layer from the glass cloth to a surface of the resin layer adjacent to the core layer.

3. The multi-layer substrate according to claim 1, wherein
the inner layer wire is disposed between the land and the core layer, and the glass cloth is extruded toward the land by the inner layer wire as an extrusion member.

4. The multi-layer substrate according to claim 1, wherein
in the build-up layer, the thickness of the resin layer located between the land and the core layer from the glass cloth to the surface of the resin layer adjacent to the land is smaller than a thickness of the resin layer in a portion outside of the land from the glass cloth to the surface of the resin layer adjacent to the land.

5. An electronic device comprising:
the multi-layer substrate according to claim 1;
the solder disposed on only the surface of the land;
the electronic component mounted over the land through the solder; and
a mold resin that seals the electronic component and the land, and comes in close contact with a side surface of the land.

6. A method of manufacturing a multi-layer substrate, comprising:
preparing a core layer having a front surface, and including an inner layer wire on the front surface;
preparing a build-up layer having a glass cloth and a resin layer on both surfaces of the glass cloth, the resin layer having the same thickness on both of the surfaces of the glass cloth;
laminating the build-up layer on the front surface of the core layer;
laminating a metal plate on a surface of the build-up layer opposite to the core layer;
deforming a portion of the glass cloth corresponding to the inner layer wire in a direction away from the core layer so that the portion of the glass cloth is extruded toward the metal plate by the inner layer wire than a portion of the glass cloth without corresponding to the inner layer wire while allowing a resin forming the resin layer of the build-up layer to flow around the inner layer wire by heating a laminated body having the core layer, the build-up layer, and the metal plate while pressurizing the laminated body in a laminating direction; and
forming a surface layer wire in a portion of the metal plate corresponding to the inner layer wire by patterning the metal plate.

7. A substrate comprising:
an insulating layer;
a first conductor arranged on one side of the insulating layer in a thickness direction of the insulating layer; and
a second conductor arranged on the other side of the insulating layer in the thickness direction, wherein
the insulating layer includes a glass cloth, and a resin layer that is made of an electrically insulating resin material, and seals a surface of the glass cloth adjacent to the first conductor and a surface of the glass cloth adjacent to the second conductor,
a linear expansion coefficient of the glass cloth is lower than a linear expansion coefficient of the first conductor, and lower than a linear expansion coefficient of a portion of the resin layer disposed adjacent to the first conductor,
a dimension between the first conductor and the glass cloth in the thickness direction of the insulating layer is defined as A, a dimension of the glass cloth in the thickness direction is defined as B, and a dimension between a surface (230b, 240b) of the insulating layer adjacent to the second conductor and the glass cloth in the thickness direction is defined as C, and
A, B, and C satisfy a size relationship of C>A>B.

8. The substrate according to claim 7, wherein
the glass cloth includes a plurality of first yarns each made of a glass fiber extending in a first direction, and a plurality of second yarns each made of a glass fiber extending in a second direction orthogonal to the first direction,
the glass cloth is woven to configure a plurality of bellies where any one of the plurality of first yarns and any one of the plurality of second yarns overlap with each other, and
the dimension B is a dimension of any one of the plurality of bellies in the thickness direction.

9. The substrate according to claim 7, wherein
the linear expansion coefficient of the resin layer is lower than the linear expansion coefficient of the first conductor.

10. The substrate according to claim 7, further comprising
a core layer that is disposed opposite to the first conductor with respect to the insulating layer, and made of an electric insulating material, wherein
the second conductor is disposed on a surface of the core layer.

11. The substrate according to claim 7, wherein
the core layer includes a glass cloth and a resin layer that is made of an electrically insulating material and seals both surfaces of the glass cloth.

12. The substrate according to claim 11, wherein
the dimension B of the glass cloth of the insulating layer in the thickness direction is smaller than a dimension of the glass cloth of the core layer in the thickness direction.

13. The substrate according to claim 12, wherein
the resin material forming the resin layer of the insulating layer is mixed with a first filter,
the resin material forming the resin layer of the core layer is mixed with a second filter, and
a rate of a mass of the first filler to a mass of the insulating layer is larger than a rate of a mass of the second filter to a mass of the core layer.

14. An electronic device comprising:
the substrate according to claim 7;
an electronic component that is disposed opposite to the insulating layer with respect to the first conductor, and joined to the first conductor; and
a mold resin member that is made of a resin material and seals the insulating layer on a side adjacent to the first conductor and the electronic component.
